(19) United States
(12) Patent Application Publication
(10) Pub. No.: US 2003/0186613 A1
(43) Pub. Date: Oct. 2, 2003

(54) Liquid material ejecting method, liquid material ejecting apparatus, color filter manufacturing method, color filter, liquid crystal device, electroluminescence device manufacturing method, electroluminescence device, plasma display panel manufacturing method, and plasma display panel

(75) Inventor: Tomomi Kawase, Matsumoto-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/372,116

(22) Filed: Feb. 25, 2003

(30) Foreign Application Priority Data
Mar. 6, 2002 (JP) 2002-060717
Jan. 17, 2003 (JP) 2003-009902

(51) Int. Cl. H01J 9/00

(52) U.S. Cl. 445/60; 445/24

(57) ABSTRACT

To provide a liquid material ejecting method and a liquid material ejecting apparatus, etc., in which uniform electro-optic characteristics, etc. are obtained in the planar direction. In the liquid material ejecting method and the liquid material ejecting apparatus, etc., a plurality of liquid materials are successively ejected toward a substrate from corresponding nozzle rows while relatively scanning a droplet ejection head or the substrate, and respective positions of ejection start and/or end points for the plurality of liquid materials are set different from each other. End portions of areas of the substrate, in which the plurality of liquid materials are applied, are thereby not or less overlapped with each other. Accordingly, with the liquid material ejecting method, variations in amount of the applied liquid materials in the planar direction can be reduced.

### BACKGROUND OF THE INVENTION

1. Field of Invention

The present invention relates to a liquid material ejecting method, a liquid material ejecting apparatus, a color filter manufacturing method and a color filter, a liquid crystal display, an electroluminescence device manufacturing method and an electroluminescence device, as well as to a plasma display panel manufacturing method and a plasma display panel.

More particularly, the present invention relates to a liquid material ejecting method, a liquid material ejecting apparatus, a color filter manufacturing method and a color filter, a liquid crystal display, an electroluminescence device manufacturing method and an electroluminescence device, as well as to a plasma display panel manufacturing method and a plasma display panel, in which applied materials having uniform electro-optic characteristics, etc. in the planar direction are obtained.

2. Description of Related Art

Recently, in display sections of electronic devices, e.g., cellular phones and portable computers, electro-optical device, display devices, such as a liquid crystal display (hereinafter also referred to as “LCD”), an electroluminescence device (hereinafter also referred to as an “EL device”) and a plasma display panel (hereinafter also referred to as a “PDP”), have been widely employed and studied with attention focused on their features of thin thickness and light weight.

In each of those display devices, full-color display is demanded. In the LCD, for example, full-color display is realized by causing light modulated by a liquid crystal layer to pass through a color filter that is disposed in a plane intersecting a travel path of the light.

The color filter is constituted, for example, by regularly arranging dot-like filter elements corresponding to R (red), G (green) and B (blue) in a predetermined array on the surface of a glass or plastic board.

Then, the photolithography is generally employed to manufacture the color filter. However, the photolithography has accompanied the problems of a higher manufacturing cost and a larger load upon environmental conditions because the manufacturing process is complicated and color filter materials, photoresists, etc. are consumed in large amount corresponding to the respective colors.

To overcome those problems with the manufacturing and the environment, a method of manufacturing the filter elements of the color filter using the so-called ink jet process is proposed. Assume, for example, the case that, in inner areas of a plurality of panel regions 302 set on the surface of a motherboard 301 shown in FIG. 31(a), a plurality of filter elements 303 are formed using the ink jet process as shown in FIG. 31(b). More specifically, as shown in FIG. 31(c), a droplet ejection head 306 having a row of nozzles 304 arrayed on a line is prepared. Then, the droplet ejection head 306 is moved for a main scan over one panel region 302 plural times (two times in an example of FIG. 31), as indicated by arrows A1 and A2 in FIG. 31(b), while color filter materials are selectively ejected from the plurality of nozzles 304 during the main scans. As a consequence, the filter elements 303 can be formed in predetermined positions.

It is however found that variations occur in amount of the ejected color filter materials depending on respective positions of the plural nozzles 304 in the droplet ejection head 306. More specifically, as shown in FIG. 32, a material ejection characteristic (Q-characteristic) is found in which the nozzles 304 in opposite end zones of a nozzle row 305 eject the color filter materials in larger amount than the nozzles 304 in a central zone.

Accordingly, when the nozzle row 305 is scanned plural times in the vertical direction on the drawing, there is a tendency that, as shown in FIG. 33(a), the amount of the materials ejected from the nozzles 304 in the opposite end zones of the nozzle row 305 is relatively large, and the amount of the materials ejected from the nozzles 304 in the intermediate zone of the nozzle row 305 is relatively small. When the filter elements 303 of the color filter are formed using the droplet ejection head 306, lines having a higher color density sometimes appear at opposite ends (P1) as shown in FIG. 33(b). Thus, the obtained color filter has a problem that light transmittance characteristics tend to be uneven in the planar direction.

In consideration of the above problem, a color filter manufacturing method is disclosed in which, when applying color filter materials onto a transparent substrate in areas to be colored while scanning a droplet ejection head or the substrate in the vertical direction, the colored areas are formed by setting the amount of the applied materials to be different between the colored area at a boundary of adjacent scanned regions and the colored area other than the boundary (see Patent Reference 1 indicated below).

More specifically, the Patent Reference 1 proposes a color filter manufacturing method in which, as shown in FIG. 34, when applying the materials to a plurality of areas to be colored while scanning droplet ejection heads 351a-351c in the vertical direction indicated by an arrow 354, an overall colored area of a substrate 352 is divided into a plurality of scanned regions 353a, 353b and 353c parallel to each other in the direction of the head scan, and the amount of the applied materials is set to be different at least between the colored area (line denoted by A) at a boundary of adjacent scanned regions and the colored area (regions denoted by 353a, 353b and 353c) other than the boundary.

[Patent Reference 1]

Japanese Unexamined Patent Application Publication No.2000-89017

### SUMMARY OF THE INVENTION

With the conventional color filter manufacturing method described above, the head operation, etc. are finely set such that the amount of the applied materials differs depending on positions to be colored. However, a problem has been experienced in that control of the head operation, etc. cannot follow situations when conditions of the ambient environment, the type and viscosity of the materials, etc. are changed to a large extent.

Such a problem has often rather increased unevenness of light transmittance characteristics in the planar direction because of the increased difference in amount of the applied materials between the colored area corresponding to the boundary of adjacent scanned regions in the color filter and the colored area other than the boundary.

As a result of conducting intensive studies in view of the problems set forth above, the inventor of the present invention has found that, even when liquid materials are applied from a droplet ejection head substantially in the same amount like the conventional method while relatively scanning the droplet ejection head or a substrate, the amount of the liquid materials applied to respective colored areas can be controlled by adjusting, e.g., end positions of nozzle rows such that respective positions of ejection start and/or end points for the liquid materials are different from each other. Based on that finding, the inventor has accomplished the present invention.

In other words, an object of the present invention is to provide a liquid material ejecting method, a liquid material ejecting apparatus, a color filter manufacturing method and a color filter, a liquid crystal display, an electroluminescence device manufacturing method and an electroluminescence device, as well as a plasma display panel manufacturing method and a plasma display panel, in which applied materials having uniform light-transmissive characteristics, etc. in the planar direction are obtained.

[Means for Solving the Problems]

According to the present invention, the above-mentioned problems can be overcome by providing a liquid material ejecting method using a droplet ejection head, wherein a plurality of liquid materials are successively ejected toward a substrate from corresponding nozzle rows while relatively scanning the droplet ejection head or the substrate, and respective positions of ejection start and/or end points for the liquid materials are set different from each other.

Thus, even when the liquid materials are applied from the droplet ejection head substantially in the same amount like the conventional method, end portions of areas of the substrate, in which the plurality of liquid materials are applied, can be made not or less overlapped with each other by applying the liquid materials such that the respective positions of the ejection start and/or end points for the liquid materials are shifted from each other.

With the liquid material ejecting method set forth above, therefore, variations in amount of the applied liquid materials in the planar direction can be reduced and hence the applied liquid materials having uniform light-transmissive characteristics, etc. in the planar direction can be obtained without changing the applying performance of the droplet ejection head.

Means for setting the respective positions of the ejection start and end points for the liquid materials to be different from each other is not limited to a particular one, and can be implemented in any of typical eight modes shown in Table 1 described later. However, it is also possible to employ a droplet ejection head having nozzle rows shown in FIG. 2, to divide each of the nozzle rows into 3 zones, e.g., left, central and right zones, corresponding to the number of liquid materials used, and to set respective positions of ejection start and end points for the three liquid materials to be different from each other under control of the operation of the droplet ejection head.

When implementing the liquid material ejecting method of the present invention, preferably, positions of both or one ends of the nozzle rows are made different from each other in one- or two-dimensional directions, whereby the respective positions of the ejection start and/or end points for the liquid materials are set different from each other.

With the method thus implemented, the respective positions of the ejection start or end points for the plurality of liquid materials on the substrate can be set different from each other just by adjusting both the end positions of the nozzle rows.

When implementing the liquid material ejecting method of the present invention, preferably, ejection widths of the plurality of liquid materials are set substantially equal to each other.

With the method thus implemented, the respective positions of the ejection start or end points for the liquid materials on the substrate can be set different from each other, for example, just by employing the droplet ejection head of a simple construction in which the ejection widths are substantially equal to each other.

When implementing the liquid material ejecting method of the present invention, preferably, the droplet ejection head is prepared in plural, and widths of the nozzle rows in a direction perpendicular to a scan direction of the droplet ejection head are set substantially equal to each other, whereby the ejection widths of the liquid materials are set substantially equal to each other.

With the method thus implemented, the respective positions of the ejection start or end points for the plurality of liquid materials on the substrate can be set different from each other just by preparing a plurality of relatively simple droplet ejection heads in which the ejection widths are substantially equal to each other. Also, since the plurality of droplet ejection heads are provided, the heads can be more finely operated corresponding to the kinds of liquid materials, and hence the respective positions of the ejection start or end points for the liquid materials can be more easily adjusted.

When implementing the liquid material ejecting method of the present invention, preferably, ejection widths of the plurality of liquid materials are set different from each other, and the positions of the ejection start points or the positions of the ejection end points for the liquid materials are set substantially coincident with each other.

With the method thus implemented, end portions of the substrate, in which the plurality of liquid materials are applied, can be less overlapped with each other, and an area in which the liquid material is not applied can be formed only on one side of the substrate.

When implementing the liquid material ejecting method of the present invention, preferably, the droplet ejection head is prepared in plural, and widths of the nozzle rows in a direction perpendicular to a scan direction of the droplet ejection head are set different from each other, whereby the ejection widths of the plurality of liquid materials are set different from each other.

With the method thus implemented, the respective positions of the ejection start or end points for the liquid materials on the substrate can be set different from each other just by changing the widths of the droplet ejection heads and operating the droplet ejection heads in the same manner as conventional.

When implementing the liquid material ejecting method of the present invention, preferably, in applying the liquid materials to end portions of the substrate using the nozzle rows, one ore more nozzle rows located outside an area of the substrate are not used, and one ore more nozzle rows located inside the area of the substrate are used.

With the method thus implemented, an area in which the plurality of liquid materials are all not applied can be reduced in an end portion of the substrate.

Another aspect of the present invention resides in a liquid material ejecting apparatus using a droplet ejection head, wherein the apparatus comprises nozzle rows provided on the droplet ejection head corresponding to a plurality of liquid materials, and a control unit for successively ejecting the plurality of liquid materials from the nozzle rows while relatively scanning the droplet ejection head or a substrate, such that respective positions of ejection start and/or end points for the liquid materials are different from each other.

Thus, even when the liquid materials are applied substantially in the same amount like the conventional method using the droplet ejection head while relatively scanning the head, end portions of areas of the substrate, in which the plurality of liquid materials are applied, can be made not or less overlapped with each other by adjusting the respective positions of the ejection start or end points for the liquid materials so as to shift from each other with the control unit.

With the liquid material ejecting apparatus set forth above, therefore, variations in amount of the applied liquid materials in the planar direction can be reduced and hence the applied materials having uniform light-transmissive characteristics, etc. in the planar direction can be obtained without changing the applying performance of the droplet ejection head.

When constructing the liquid material ejecting apparatus of the present invention, preferably, the droplet ejection head is arranged obliquely with respect to a moving direction of the droplet ejection head.

With the apparatus thus constructed, the interval at which the liquid material is ejected can be made smaller than the actual pitch of the nozzle row, and therefore the applied material can be formed in a finer pattern. Also, with the apparatus thus constructed, even when a plurality of droplet ejection heads are provided, it is possible to prevent the adjacent droplet ejection heads from interfering with each other, and consequently to reduce the unit size. In addition, with the apparatus thus constructed, even when the substrate size is changed to some extent, the liquid materials can be applied to the overall substrate surface by changing the cross angle of the droplet ejection head as required.

When constructing the liquid material ejecting apparatus of the present invention, preferably, the nozzle rows corresponding to the plurality of liquid materials are arranged on one droplet ejection head.

With the above-described construction, an ejecting apparatus of a simple structure is obtained, which is able to form the applied materials such that the respective positions of the ejection start or end points for the plurality of liquid materials are not overlapped with each other, while ensuring simple operation of the droplet ejection head itself.

When constructing the liquid material ejecting apparatus of the present invention, preferably, the nozzle rows corresponding to the plurality of liquid materials are disposed respectively on a plurality of droplet ejection heads.

With the above-described construction, an ejecting apparatus is provided which is able to form the applied materials such that the respective positions of the ejection start or end points for the plurality of liquid materials on the substrate are set different from each other, just by preparing a plurality of relatively simple droplet ejection heads in which the ejection widths are substantially equal to each other. Also, since the plurality of droplet ejection heads are provided, the heads can be more finely operated corresponding to the kinds of liquid materials, and hence the respective positions of the ejection start or end points for the plurality of liquid materials can be more easily adjusted.

A still another aspect of the present invention resides in a color filter manufacturing method and a color filter manufactured by the method, wherein a plurality of color filter materials are successively ejected from corresponding nozzle rows while relatively scanning a droplet ejection head or a substrate, and respective positions of ejection start and/or end points for the color filter materials are set different from each other.

With the method set forth above, variations in amount of the applied color filter materials in the planar direction can be reduced and hence a color filter having uniform light-transmissive characteristics, etc. in the planar direction can be obtained without changing the applying performance of the droplet ejection head.

A still another aspect of the present invention resides in a liquid crystal display including the color filter described above.

Since the liquid crystal display includes the color filter having uniform light-transmissive characteristics, etc. in the planar direction, a color image with stable brightness in the planar direction can be observed.

A still another aspect of the present invention resides in an electroluminescence device manufacturing method and an electroluminescence device manufactured by the method, wherein a plurality of electroluminescence materials are successively ejected from corresponding nozzle rows while relatively scanning a droplet ejection head or a substrate, and respective positions of ejection start and/or end points for the electroluminescence materials are set different from each other.

With the method set forth above, variations in amount of the applied electroluminescence materials in the planar direction can be reduced and hence an electroluminescence device having uniform EL light-emitting characteristics, etc. in the planar direction can be obtained without changing the applying performance of the droplet ejection head.

A still another aspect of the present invention resides in a plasma display panel manufacturing method and a plasma display panel manufactured by the method, wherein a plurality of plasma luminous materials are successively ejected from corresponding nozzle rows while relatively scanning a droplet ejection head or a substrate, and respective positions of ejection start and/or end points for the plasma luminous materials are set different from each other.

With the method set forth above, variations in amount of the applied plasma luminous materials in the planar direction can be reduced and hence a plasma display panel having uniform plasma luminous characteristics, etc. in the planar direction can be obtained without changing the applying performance of the droplet ejection head.

The details of the plasma display panel manufacturing method and a plasma display panel manufactured by the method are not limited to particular ones, and can be implemented, by way of example, as a plasma display panel 500 shown in FIG. 29.

Also, according to still another aspect of the present invention, a liquid material ejecting method comprises a scanning step of successively, from a plurality of nozzle rows, corresponding different liquid materials toward a substrate while scanning the plurality of nozzle rows or the substrate in a predetermined direction, wherein, in the scanning step, an area of the substrate, over which one of the plurality of nozzle rows passes, is partly overlapped with an area of the substrate, over which another nozzle row passes, and both end positions of one of the plurality of nozzle rows are different from both end positions of another nozzle row in a direction perpendicular to the predetermined direction.

Further, according to still another aspect of the present invention, a liquid material ejecting method comprises a scanning step of successively, from a plurality of nozzle rows, corresponding different liquid materials toward a substrate while scanning the plurality of nozzle rows or the substrate in a predetermined direction, wherein, in the scanning step, an area of the substrate, over which one of the plurality of nozzle rows passes, is partly overlapped with an area of the substrate, over which another nozzle row passes, a first end position of one of the plurality of nozzle rows is substantially the same as a first end position of another nozzle row in a direction perpendicular to the predetermined direction, and a second end position of one of the plurality of nozzle rows is different from a second end position of another nozzle row in the direction perpendicular to the predetermined direction.

Moreover, according to still another aspect of the present invention, a liquid material ejecting method comprises a scanning step of successively ejecting, from first, second and third nozzle rows, corresponding first, second and third liquid materials toward a substrate while scanning the first, second and third nozzle rows or the substrate in a predetermined direction, wherein, in the scanning step, areas of the substrate, over which the first, second and third nozzle rows pass, are partly overlapped with each other, and both end positions of the first, second and third nozzle rows are different from each other in a direction perpendicular to the predetermined direction.

Furthermore, according to still another aspect of the present invention, a liquid material ejecting method comprises a scanning step of successively ejecting, from first, second and third nozzle rows, corresponding first, second and third liquid materials toward a substrate while scanning the first, second and third nozzle rows or the substrate in a predetermined direction, wherein, in the scanning step, areas of the substrate, over which the first, second and third nozzle rows pass, are partly overlapped with each other, first end positions of the first, second and third nozzle rows are substantially the same in a direction perpendicular to the predetermined direction, and second end positions of the first, second and third nozzle rows are different from each other in the direction perpendicular to the predetermined direction.

In the liquid material ejecting method, the liquid material ejecting apparatus, the color filter manufacturing method, the color filter, the liquid crystal display, the electroluminescence device manufacturing method, the electroluminescence device, the plasma display panel manufacturing method, and the plasma display panel, which have been set forth above, a plurality of droplet ejection heads are preferably employed as an integral unit in a state in which the heads are fixedly arranged in a predetermined array relative to each other.

To that end, the plurality of droplet ejection heads are sometimes arranged such that an essentially integral nozzle row is formed in the unit. In this case, as one arrangement, nozzles are arrayed continuously (at equal intervals) in the essentially integral nozzle row. Such an arrangement can be realized by arranging the plurality of droplet ejection heads at positions alternately shifted in the scan direction. As another arrangement, the essentially integral nozzle row is formed so as to have a plurality of ejection widths t arranged with a predetermined spacing s therebetween. In the case of employing that arrangement, the spacing s and the ejection width t are preferably equal to each other. When implementing the present invention, it is preferable that the above-mentioned unit is provided in plural and the respective positions of the ejection start and/or end points are set different from each other between or among the essentially serial nozzle rows on the plurality of units.

Also, when a plurality of droplet ejection heads are provided in the unit, a plurality of nozzle rows are sometimes provided on each of the droplet ejection heads. In this case, preferably, the respective positions of the ejection start and/or end points are set different from each other between or among the plurality of nozzle rows.

Further, when a plurality of droplet ejection heads are provided in the unit, it is preferable that the respective positions of the ejection start and/or end points are set different from each other between or among the plurality of droplet ejection heads.

### BRIEF DESCRIPTION OF THE DRAWINGS

FIG. 1 is a schematic view of a droplet ejection head of the present invention.

FIG. 1(a) is a perspective view partly cut out.

FIG. 1(b) is a sectional view taken along a line J-J.

FIG. 2 is an illustration for explaining nozzle rows in the droplet ejection head of the present invention.

FIG. 3 is a (first) illustration for explaining relationships between the droplet ejection heads (nozzle rows) of the present invention and respective positions of ejection start and end points for the plurality of liquid materials.

FIG. 4 is a (second) illustration for explaining relationships between the droplet ejection heads (nozzle rows) of the present invention and respective positions of ejection start and end points for the plurality of liquid materials.

FIG. 5 is a (third) illustration for explaining relationships between the droplet ejection heads (nozzle rows) of the present invention and respective positions of ejection start and end points for the plurality of liquid materials.

FIG. 6 is a (fourth) illustration for explaining relationships between the droplet ejection heads (nozzle rows) of the present invention and respective positions of ejection start and end points for the plurality of liquid materials.

FIG. 7 is a (fifth) illustration for explaining relationships between the droplet ejection heads (nozzle rows) of the present invention and respective positions of ejection start and end points for the plurality of liquid materials.

FIG. 8 is a schematic view of a droplet ejection unit, showing Arrangement Example 1 of a second embodiment.

FIG. 9 is an explanatory view showing a manner of usage for Arrangement Example 1.

FIG. 10 is a schematic view of a droplet ejection unit, showing Arrangement Example 2 of the second embodiment.

FIG. 11 is an explanatory view showing a manner of usage for Arrangement Example 2.

FIG. 12 is an explanatory view showing a scan method for Arrangement Example 2.

FIG. 13 is a schematic view of a droplet ejection unit, showing Arrangement Example 3 of the second embodiment.

FIG. 14 is a schematic view of a droplet ejection unit, showing Arrangement Example 4 of the second embodiment.

FIG. 15 is a schematic view showing another form of Arrangement Example 4.

FIG. 16 is a perspective view showing one example of a liquid crystal display.

FIG. 17 is a schematic view showing a modification of the droplet ejection heads (nozzle rows) of the present invention.

FIG. 18 is a block diagram for explaining the operation of an ejecting apparatus of the present invention.

FIG. 19 is a set of illustrations for explaining successive steps of manufacturing a color filter.

FIG. 20 is an illustration showing examples of array of color elements in the color filter.

FIG. 21 is an illustration for explaining a motherboard used in the steps of manufacturing the color filter.

FIG. 22 is a graph showing the relationship between measurement positions and light transmittance in the color filter.

FIG. 22(a) shows an example of measurement for the color filter of the present invention.

FIG. 22(b) shows an example of measurement for a conventional color filter.

FIG. 23 is a schematic view of a liquid crystal display of the present invention.

FIG. 24 is a diagram showing a driving circuit for an active matrix electroluminescence display.

FIG. 25 is a (first) set of illustrations for explaining successive steps of manufacturing the electroluminescence display.

FIG. 26 is a (second) set of illustrations for explaining successive steps of manufacturing the electroluminescence display.

FIG. 27 is a (third) set of illustrations for explaining successive steps of manufacturing the electroluminescence display.

FIG. 28 is a sectional view for explaining a general structure of a PDP (Plasma Display Panel).

FIG. 29 is an exploded perspective view showing a structure of a plasma display panel of a sixth embodiment.

FIG. 30 is a vertical sectional view of the plasma display panel of the sixth embodiment.

FIG. 31 is a set of illustrations for explaining the operation of a droplet ejection head (nozzle row) in a process of manufacturing a conventional color filter.

FIG. 32 is an illustration for explaining an internal structure of a conventional droplet ejection head (nozzle row).

FIG. 33 is a set of illustrations for explaining a Q-characteristic in the conventional droplet ejection head (nozzle row).

FIG. 34 is an illustration for explaining the relationship between the operation of the droplet ejection head (nozzle row) and boundary lines in the process of manufacturing the conventional color filter.

### DETAILED DESCRIPTION OF PREFERRED EMBODIMENTS

Embodiments of a liquid material ejecting method, a liquid material ejecting apparatus, a color filter manufacturing method, a color filter, a liquid crystal display using the color filter, an electroluminescence device manufacturing method, an electroluminescence device, a plasma display panel manufacturing method, and a plasma display panel, according to the present invention, will be described below in detail with reference to the drawings as required.

[First Embodiment]

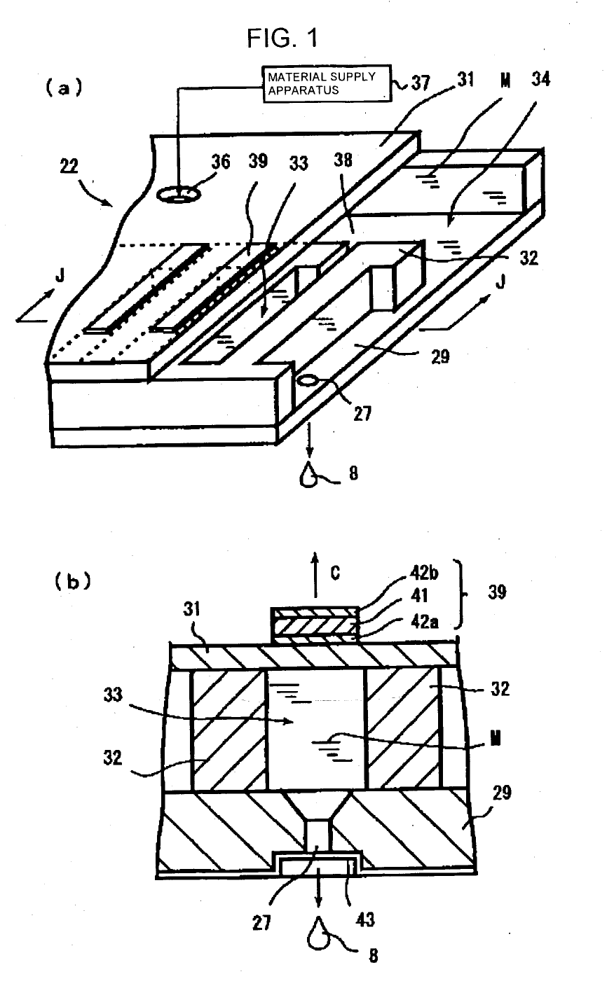

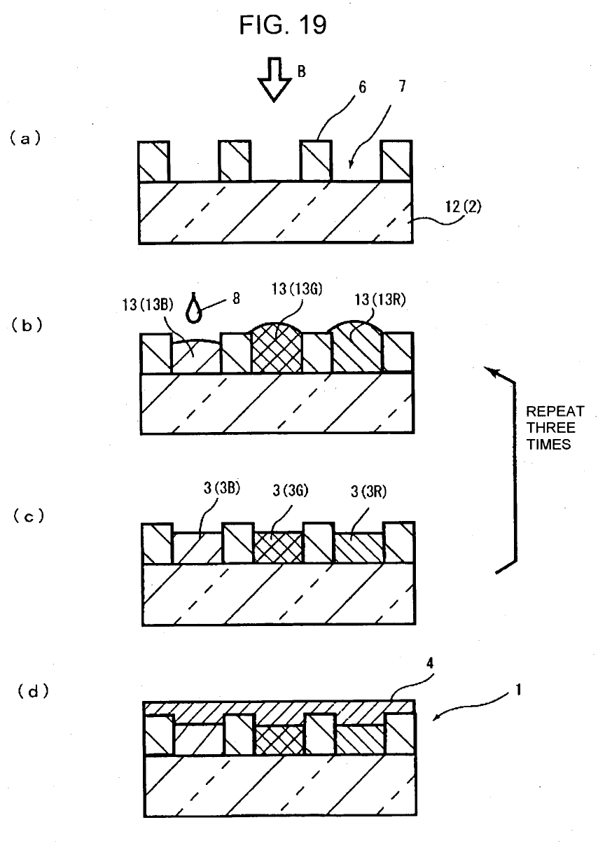

A first embodiment represents a liquid material ejecting method using a droplet ejection head 22, as shown in FIG. 1, in which a plurality of liquid materials are successively ejected toward a substrate 2 (see FIG. 19) from corresponding nozzle rows 27 while relatively scanning the droplet ejection head 22 or the substrate 2, and respective positions of ejection start and/or end points for the liquid materials are set different from each other.

Requirements for an ejection mechanism, a plurality of liquid materials, a substrate, and an ejection method, which constitute the first embodiment, will be described below in detail.

1. Ejection Mechanism and Ejection Method

(1) Ejection Mechanism

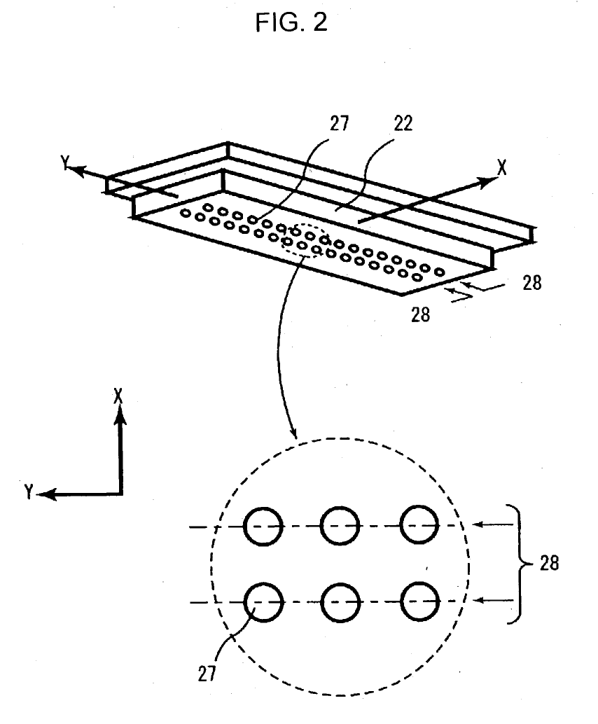

In the ejection mechanism used in the first embodiment, preferably, a plurality of liquid materials, i.e., at least two or more same or different kinds of liquid materials, are ejected from corresponding nozzle rows by a method employing piezoelectric devices, for example. More specifically, as shown in FIGS. 1(a) and 1(b), it is preferable that a plurality of liquid materials 8, e.g., three kinds of color filter materials corresponding to RGB pixels or YMC pixels, are ejected from the droplet ejection head 22 provided with the nozzle rows 27, shown in FIG. 2, by utilizing flexural deformations of piezoelectric devices 41. FIG. 1(a) is a perspective view, partly cut out, of the droplet ejection head 22 provided with the nozzle rows 27, and FIG. 1(b) is a sectional view of the droplet ejection head 22 provided with the nozzle rows 27 taken along a line J-J shown in FIG. 1(a). FIG. 2 is a set of a perspective view of the droplet ejection head 22 shown in FIGS. 1(a) and 1(b), and a partial enlarged view of the nozzle rows.

With the method using the droplet ejection head 22, the liquid materials supplied to flow into the droplet ejection head 22 in the direction of arrows 28 in FIG. 2 can be stably ejected as small droplets from the nozzle rows 27 regardless of the type of a solvent, etc. contained in the liquid materials by energizing the piezoelectric devices 41 disposed at the top of the droplet ejection head 22.

Any other method is also usable so long as the method enables a plurality of small liquid materials to be successively ejected. For example, the so-called heating method of ejecting materials by utilizing bubbles generated upon heating is also preferably usable to implement the first embodiment.

(2) Droplet Ejection Head and Nozzle Row

Droplet Ejection Head

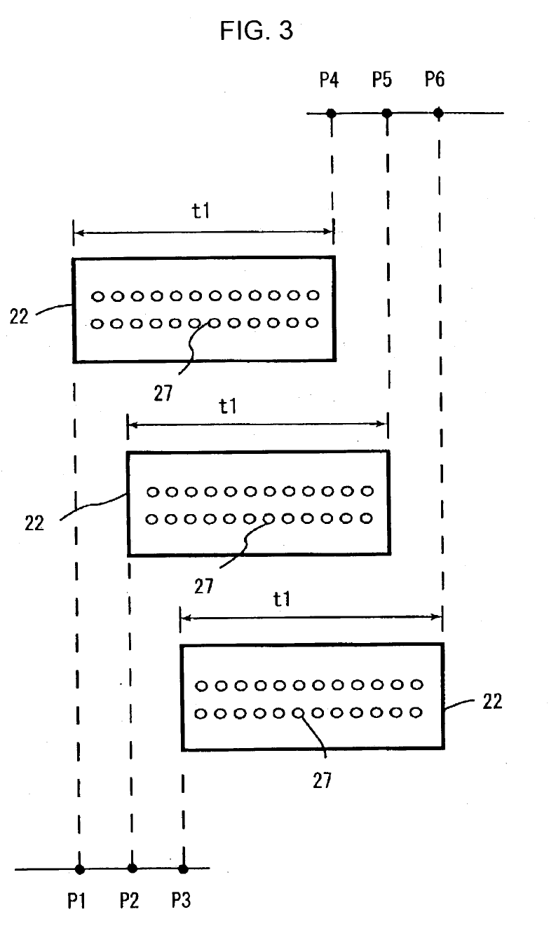

In the first embodiment, preferably, the droplet ejection heads 22 is prepared in plural and the nozzle rows 27 corresponding to the plurality of liquid materials are provided in the droplet ejection heads 22 as shown in, by way of example, FIGS. 3 to 6. For example, the plurality of droplet ejection heads corresponding respectively to color filter materials for RGB pixels or YMC pixels, and the nozzle rows for ejecting the materials for RGB pixels or YMC pixels are provided in the respective droplet ejection heads.

With the arrangement described above, fine drawing can be realized with the nozzle rows corresponding to the plurality of liquid materials just by controlling the respective droplet ejection heads, as required, by a CPU, etc. so as to perform predetermined operations. In the case of preparing, e.g., three droplet ejection heads depending on evaporation characteristics, etc. of the plurality of liquid materials, therefore, it is easily possible to apply the liquid material once by operating one droplet ejection head once, to apply the liquid materials in a double-overlapped relation by operating another droplet ejection head once, and to apply the liquid materials in a triple-overlapped relation by operating still another droplet ejection head once.

Also, in the case of preparing the plurality of droplet ejection heads, widths over which the plurality of liquid materials are ejected can be made substantially equal to each other just by setting widths of the plurality of droplet ejection heads in a direction perpendicular to the head scan direction to be substantially equal to each other. By setting respective positions of ejection start and/or end points for the plurality of liquid materials to be different from each other, therefore, variations in amount of the applied liquid materials in the planar direction due to differences in positions, at which the liquid materials are applied, can be reduced and the so-called Q-characteristic can be prevented. As a result, the applied materials having uniform electro-optic characteristics can be obtained.

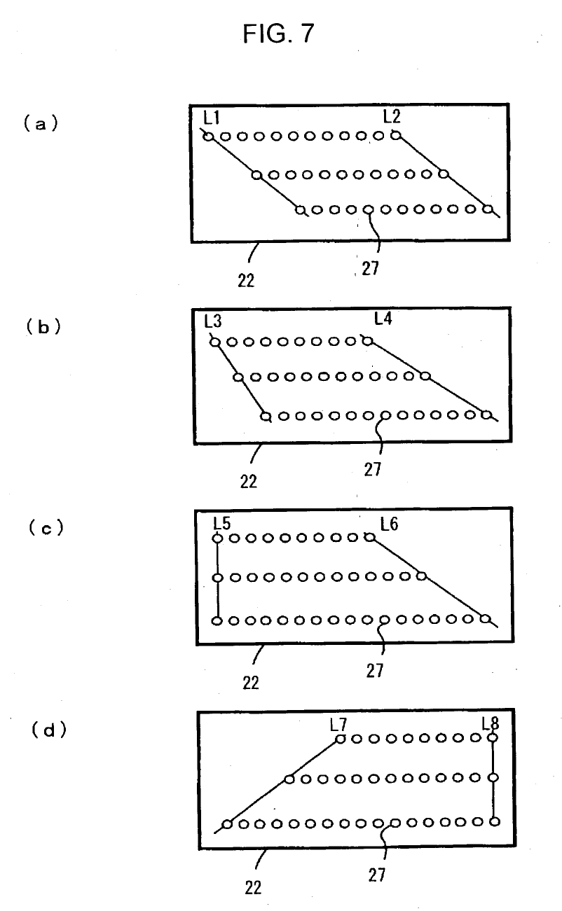

In the first embodiment, it is also preferable that, as shown in FIGS. 7(a) to 7(d), a single droplet ejection head 22 is prepared and nozzle rows 27 corresponding to the plurality of liquid materials are provided in the droplet ejection head 22.

With the above arrangement, an applying device can be constructed in a smaller size as a whole. For example, by preparing a single droplet ejection head and providing three nozzle rows in the droplet ejection head corresponding to three liquid materials, not only the area occupied by the droplet ejection head, but also the area occupied by a driving device, etc. for the droplet ejection head can be reduced in comparison with the case of preparing three droplet ejection heads.

Furthermore, in the case of preparing a single droplet ejection head and providing nozzle rows in the droplet ejection head corresponding to the plurality of liquid materials, the widths over which the plurality of liquid materials are ejected can be made substantially equal to each other with more ease, as described later in more detail. Just by setting respective positions of ejection start points for the plurality of liquid materials to be shifted so as not to overlap with each other, respective positions of ejection end points for the liquid materials can also easily be shifted from each other. The above-described point is represented by inclined straight lines L1, L2, L3, L4, L6 and L7 shown in FIGS. 7(a) to 7(d).

Ejection Width

In the first embodiment, as shown in FIG. 3 or 7(a), it is preferable that ejection widths of the nozzle rows corresponding to the plurality of liquid materials are set substantially equal to each other.

For example, as shown in FIG. 3, when the ejection width of the nozzle row for a first liquid material is set to t1 (mm), the ejection width of the nozzle row for a second liquid material and the ejection width of the nozzle row for a third liquid material are each also set to t1 (mm).

With that arrangement, just by setting respective positions (P1, P2, P3) of ejection start points for the plurality of liquid materials to be shifted so as not to overlap with each other, respective positions (P4, P5, P6) of ejection end points for the liquid materials are also shifted from each other correspondingly.

Accordingly, the liquid materials are prevented from being repeatedly applied in a too much amount at the ejection start and end points, and variations in amount of the applied liquid materials in the planar direction are reduced. Hence, the resulting applied materials can be given with uniform electro-optic characteristics, etc.

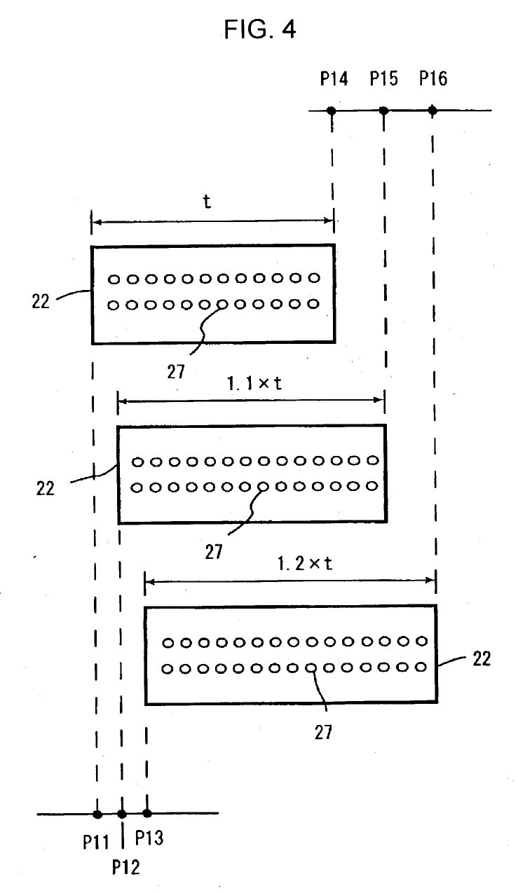

In the first embodiment, it is also preferable that, as shown in FIGS. 4 to 6 and FIG. 7(b to 7(d), the ejection widths of the nozzle rows corresponding to the plurality of liquid materials are set differently from each other.

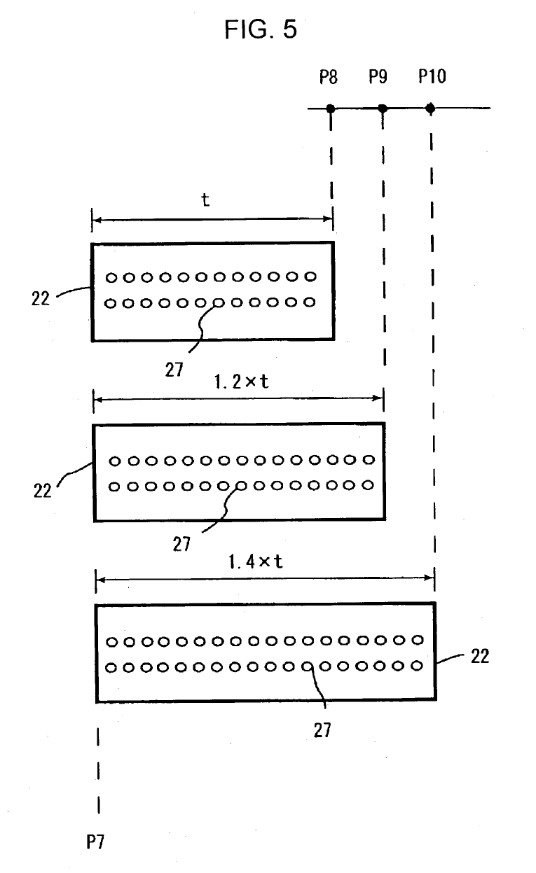

For example, as shown in FIG. 5, when the ejection width of the nozzle row for the first liquid material is set to t (mm), the ejection width of the nozzle row for the second liquid material is set to 1.2×t (mm), and the ejection width of the nozzle row for the third liquid material is set to 1.4×t (mm).

With the above-described arrangement, even when respective positions (P7) of ejection start points for the plurality of liquid materials are coincident with each other, respective positions (P8, P9, P10) of ejection end points for the liquid materials can be shifted from each other corresponding to the respective ejection widths of the nozzle rows. Accordingly, the liquid materials are prevented from being repeatedly applied in a larger amount at the ejection end points, and variations in amount of the applied liquid materials in the planar direction are reduced. It is hence possible to effectively prevent color unevenness from being observed at the boundary of adjacent scanned regions. As a result, uniform electro-optic characteristics can be obtained.

End Position of Nozzle Row

In the first embodiment, setting both or at least one of opposite ends of the nozzle rows corresponding to the plurality of liquid materials to be different from each other is one means for setting the respective positions of the ejection start and end points to be different from each other as described later. The respective positions of the ejection start and end points are preferably set different from each other as shown in, by way of example, FIGS. 3 to 7.

With the shown arrangements, the respective positions of the ejection start and/or end points for the plurality of liquid materials can be set different from each other by utilizing all of nozzle holes in each nozzle row.

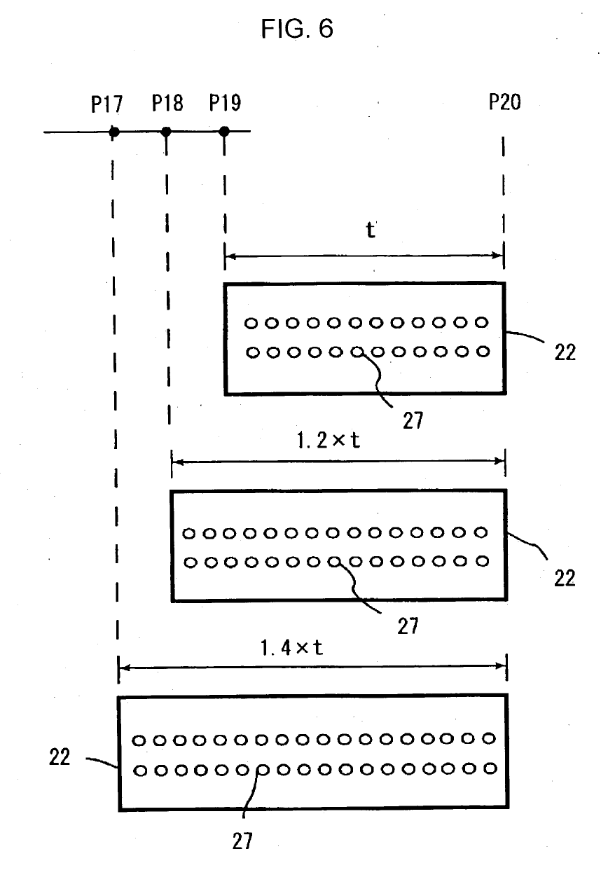

FIGS. 3 and 4 represent examples in which, in a plurality of droplet ejection heads, respective positions of both of opposite ends of the nozzle rows are set different from each other. FIGS. 5 and 6 represent examples in which, in a plurality of droplet ejection heads, respective positions of one ends of the nozzle rows are set different from each other. FIG. 7 represents examples in which, in a single droplet ejection head, respective positions of both of opposite ends of the nozzle rows are set different from each other.

(3) Ejection Start Point and Ejection End Point

The first embodiment is featured in that, as shown in FIGS. 3 to 7, the respective positions of the ejection start and/or end points for the plurality of liquid materials are set different from each other. In the case of FIG. 3, for example, the respective positions P1, P2 and P3 of the ejection start points are set different from each other and the respective positions P4, P5 and P6 of the ejection end points are also set different from each other among the plurality of droplet ejection heads.

The reasons why such an arrangement should be employed are as follows. If the respective positions of the ejection start and end points for the plurality of liquid materials are the same contrary to the first embodiment, the plurality of liquid materials, e.g., color filter materials of RGB, are repeatedly applied in larger amount at the ejection start and end areas because of the above-mentioned material ejection characteristic (Q-characteristic). In the case of the respective positions of the ejection start and end areas being coincident with each other, therefore, variations in amount of the applied materials depending on differences in position in the planar direction are increased to such an extent that unevenness in color is observed at the boundary of adjacent scanned regions, or light transmissive characteristics, etc. become uneven in the planar direction.

Also, when setting the respective positions of the ejection start and/or end points for the plurality of liquid materials to be shifted from each other, the size of the position shift is preferably set to, e.g., a value resulting from dividing the ejection width by the number of kinds of the liquid materials to be applied.

For example, when three kinds of liquid materials, e.g., color filter materials corresponding to RGB pixels, are prepared and the ejection width for each of the liquid materials is set to 3t (mm), the size of the position shift is preferably set to t (mm) that is a value resulting from dividing the ejection width (3t) by the number (3) of kinds of the liquid materials to be applied. With such setting, the ejection start and end points for the plurality of liquid materials are arranged in an evenly distributed relation for the respective applied materials, and hence variations in amount of the applied materials in the planar direction are further reduced.

In practice, the size of the shift in respective positions of the ejection start and end points for the plurality of liquid materials is preferably set to a value in the range of 0.1 to 50 mm. This is because, if the size of the position shift is less than 0.1 mm, unevenness in color would be often observed at the boundary of adjacent scanned regions. On the other hand, if the size of the position shift exceeds 50 mm, the area of a non-applied zone in which any of the liquid materials is not applied would be often too increased.

Therefore, the size of the shift in respective positions of the ejection start and end points for the plurality of liquid materials is more preferably set to a value in the range of 0.2 to 30 mm, and even more preferably in the range of 0.3 to 15 mm.

In not only the first embodiment, but also other embodiments described later, the positions of the ejection start points for the plurality of liquid materials mean printing positions (start points) where the applied materials are essentially printed at the time when the ejection of the plurality of liquid materials is started. Also, when all of nozzle holes in the nozzle row are utilized for applying the liquid material, the position of the ejection start point is essentially coincident with the end position of the nozzle row.

Likewise, the positions of the ejection end points for the plurality of liquid materials mean printing positions (end points) where the applied materials are essentially printed at the time when the ejection of the plurality of liquid materials is ended. Also, when all of nozzle holes in the nozzle row are utilized for applying the liquid material, the position of the ejection end point is essentially coincident with the end position of the nozzle row.

Also, as shown in FIGS. 3 to 7, a short distance is usually left between the edge of the droplet ejection head and the end position of the nozzle row. In such an arrangement, the respective positions of the ejection start and end points can be regarded as the opposite edges of the droplet ejection head.

As examples of the arrangement for setting the respective positions of the ejection start and/or end points for the plurality of liquid materials to be different from each other in the first embodiment, modes shown in Table 1, given below, can be conceived with regards to the number of droplet ejection heads and the ejection width of the liquid material. For easier understanding of the arrangement examples, the drawing numbers corresponding to the arrangement examples are also listed in the table.

TABLE 1

| | Droplet | | | | |
|---|---|---|---|---|---|
| | Ejection | Ejection | Ejection Start | Ejection End | Correspond-ing |
| Mode | Head | width | Points | Points | Drawing No. |
| 1 | single | equal | differ | differ | FIG. 7(a) |
| 2 | single | differ | differ | differ | FIG. 7(b) |
| 3 | single | differ | coincide | differ | FIG. 7(c) |
| 4 | single | differ | differ | coincide | FIG. 7(d) |
| 5 | plural | equal | differ | differ | |
| 6 | plural | differ | differ | differ | |
| 7 | plural | differ | coincide | differ | |
| 8 | plural | differ | differ | coincide | |

2. Plurality of Liquid Materials

(1) Kinds

The kind of the plurality of liquid materials is not limited to a particular one. Examples of the plurality of liquid materials include pigment inks, dye inks, color filter materials (referred to also as filter element materials), electroluminescence materials (including hole transporting materials, electron transporting materials, etc.), and plasma luminous materials.

Preferably, the kinds of the plurality of liquid materials are selected as appropriate, and the amount of solvent, etc. is determined such that the solution viscosity has a value within the range of, for example, 1 to 30 mPa·s (measurement temperature: 25° C., this is similarly applied to the following description).

The reason is as follows. If the solution viscosity is smaller than 1 mPa·s, it would be often practically difficult to obtain the applied material in the form of a thick film. On the other hand, if the solution viscosity exceeds 30 mPa·s, problems would often occur in that the nozzles are clogged or a difficulty arises in forming the applied material with a uniform thickness. To achieve more satisfactory balance between an increase in thickness of the applied material and evenness in thickness of the applied material, therefore, the kinds of the plurality of liquid materials are selected as appropriate, and the solution viscosity is more preferably set to a value within the range of 2 to 10 mPa·s, and even more preferably a value within the range of 3 to 8 mPa·s.

Also, it is preferably that the solution viscosity of the plurality of liquid materials is selected as appropriate depending on the usage of the applied materials. In the case of forming a color filter, for example, the solution viscosity is more preferably set to a value within the range of 6 to 8 mPa·s because the applied materials in the form of thicker films are desired from the viewpoint of color purity.

(2) Applied Materials

The kind of applied materials constituted by the plurality of liquid materials is not limited to a particular one. Examples of the applied materials include a later-described color filter made up of color filter materials (referred to also as filter element materials), a luminous medium in an electroluminescence device, and a luminous medium (phosphor) in a plasma display panel.

3. Substrate

The kind of substrate, onto which the liquid materials are applied, is also not limited to a particular one. For example, a polyester film, a polysulfone film, a polypropylene film, an acetic cellulose film, a TAC film, a glass board, a ceramic board, etc. are preferably used as the substrate.

Further, the thickness of the substrate is not limited to a particular one. For example, the substrate thickness is preferably set to a value within the range of 10 μm to 5 mm.

[Second Embodiment]

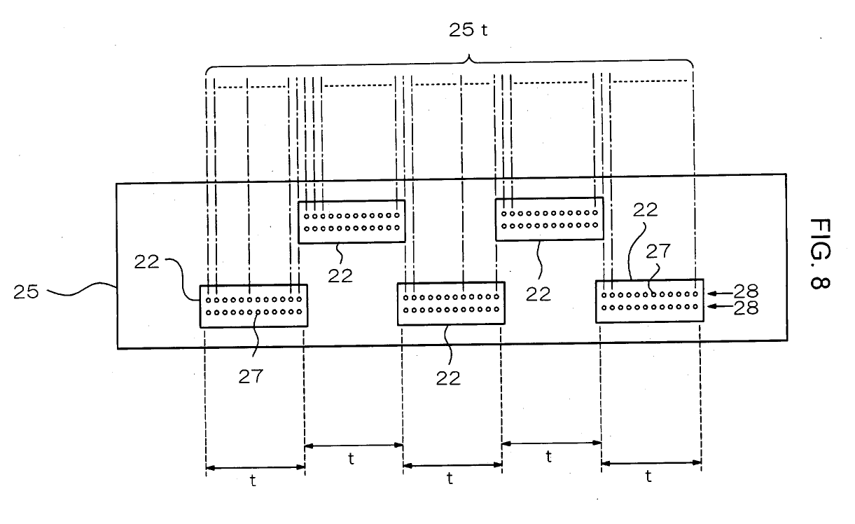

A second embodiment of the present invention will be described with reference to FIGS. 8 to 15. The second embodiment is featured in that a plurality of droplet ejection heads are arranged in a predetermined array and employed as one droplet ejection unit in the state of a head array. Usually, the shape, array pattern, size (area), etc. of a film structure (planar pattern) to be formed with droplet ejection varies depending on the usage, type, model, etc. of an object to be manufactured (such as a substrate). Preparing droplet ejection heads respectively adapted for individual objects to be manufactured for the purpose of forming such various film structures, however, increases the manufacturing cost and causes a deterioration of the manufacturing efficiency. In this second embodiment, taking into account the above-described situation, a plurality of droplet ejection heads are arranged in a predetermined array as one integral unit to constitute a nozzle array depending on the shape, array pattern, size, etc. of the object to be manufactured.

### ARRANGEMENT EXAMPLE 1

In Arrangement Example 1 shown in FIG. 8, a plurality of droplet ejection heads 22 are mounted on a sub-carriage 25. The droplet ejection heads 22 are each basically of a similar arrangement to that of the droplet ejection head 22 described in the first embodiment. As with the above-described droplet ejection head, a plurality of nozzles 27 are provided in each of the droplet ejection heads 22, and the nozzles 27 are arranged in a predetermined direction to form a nozzle row 28. In the illustrated example, two nozzle rows 28 are formed in each droplet ejection head 22. The number of the nozzle rows 28 formed on one droplet ejection head 22 is not limited to two as in the illustrated example, but may be one or three or more.

The plurality of droplet ejection heads 22 are employed in a similar way to the single droplet ejection head shown in FIGS. 3 to 6 in connection with the first embodiment, while the heads 22 are fixed on the sub-carriage 25. Also, in use, the droplet ejection heads 22 are each operated in an attitude similarly set to that in the first embodiment with respect to the scan direction (main scan direction) and a direction (sub-scan direction) perpendicular to the scan direction. When the pitch of the plurality of nozzles 27 formed in the droplet ejection head 22 (i.e., the nozzle period of the nozzle row 28) is not matched with the object to be manufactured, the droplet ejection head 22 can be used in an attitude such that the array direction of the nozzle array 28 is inclined at a predetermined inclination angle (usually an angle of larger than 0 degree but smaller than 90 degrees, and typically an angle of not larger than 60 degrees) relative to the direction perpendicular to the scan direction.

The plurality of droplet ejection heads 22 are arranged in the direction (left-and-right direction on the drawing) perpendicular to the scan direction (up-and-down direction on the drawing). Also, the plurality of droplet ejection heads 22 are arranged at different positions as viewed in the scan direction.

More specifically, the droplet ejection heads 22 are arranged in two rows in the scan direction. Looking at the droplet ejection heads 22 in the direction perpendicular to the scan direction, the heads 22 are arranged so as to locate in positions alternately shifted to the downstream and upstream sides in the scan direction. Then, the nozzles 27 provided on the plurality of droplet ejection heads 22 are arranged on the sub-carriage 25 at equal intervals in the direction perpendicular to the scan direction as a whole.

In general, the nozzles 27 cannot be provided in the vicinity of the end of the droplet ejection head 22 because of structural restrictions. Even if the nozzles 27 can be provided in the vicinity of the end of the droplet ejection head 22, ejection characteristics would be greatly deteriorated. Accordingly, an area where the nozzle 27 is not formed is present in the vicinity of the end of the droplet ejection head 22, and if the plurality of droplet ejection heads 22 are linearly arranged, the area where the nozzle 27 is not present would occur in a portion adjacent to the end of the droplet ejection head 22. In view of such a drawback, the plurality of droplet ejection heads 22 are arranged in a zigzag pattern as described above so that the nozzles 27 are arranged over the plurality of droplet ejection heads 22 at equal intervals in the direction perpendicular to the scan direction.

In this embodiment, by arranging the plurality of droplet ejection heads 22 each having an ejection width t, a total ejection width 25t resulting from adding up all the ejection widths t of the plurality of droplet ejection heads 22 is obtained as a whole. In the illustrated example, the nozzle rows 28 in the plurality of droplet ejection heads 22 all have the same ejection width t, but the nozzle rows 28 may have different ejection widths t from each other. Additionally, the plurality of droplet ejection heads 22 may be each of any suitable structure so long as the nozzles 27 are continuously arranged over the plurality of droplet ejection heads 22.

The sub-carriage 25 including the plurality of droplet ejection heads 22 mounted thereon as described above is assembled in, e.g., a head unit 26 in a third embodiment (described later) and is moved in the scan direction (main scan direction X) and the direction (sub-scan direction Y) perpendicular to the scan direction by relatively driving the head unit 26 with respect to the object to be manufactured (substrate).

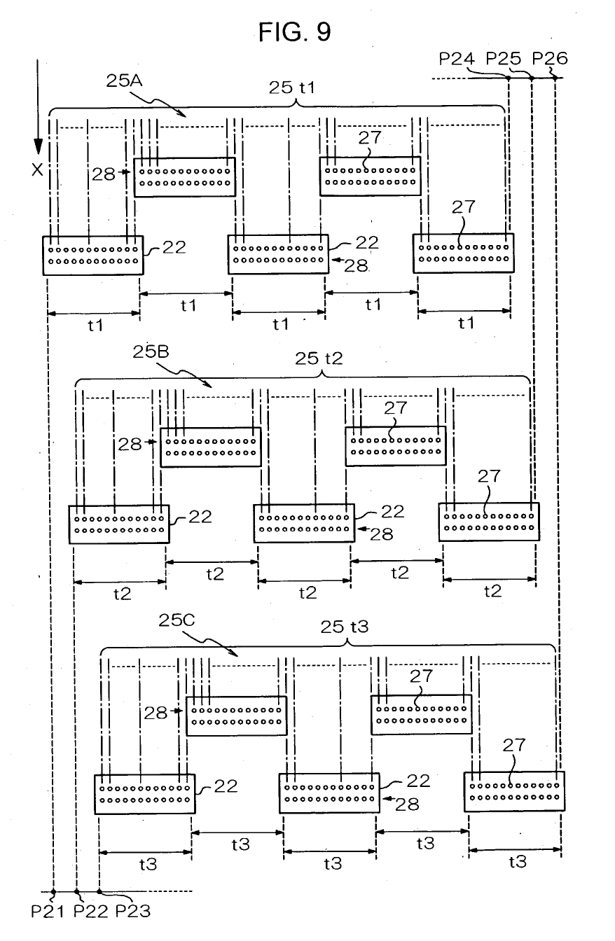

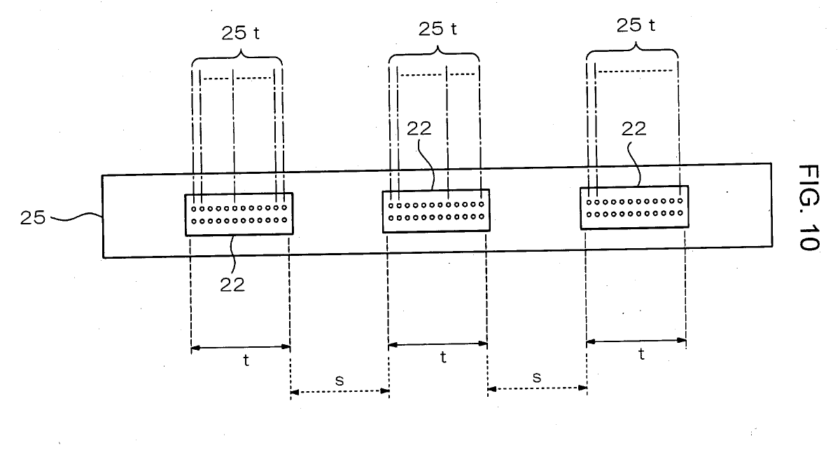

FIG. 9 represents an example in which a set of plural droplet ejection heads 22 arranged as described above is provided in plural, and shows the relative positional relationships among the plural sets during use of the droplet ejection heads 22 with the object to be manufactured (not shown) being a reference. Assume here that plural sets of the droplet ejection heads 22, each set being shown in FIG. 8, are called droplet ejection units 25A, 25B and 25C. These plural droplet ejection units 25A, 25B and 25C are used in an attitude such that the nozzle rows 28 in all the units are arranged in the same direction.

In the illustrated example, all the droplet ejection units 25A, 25B and 25C include the droplet ejection heads 22 having the same shape and the same array mode. Also, the droplet ejection units 25A, 25B and 25C as a whole have total ejection widths 25t1, 25t2 and 25t3 resulting from adding up respective ejection widths t1, t2 and t3 of the individual droplet ejection heads 22. The illustrated example shows a construction in which the respective ejection widths t1 to t3 are equal to each other and hence the total ejection widths 25t1 to 25t3 are also equal to each other. Then, the plurality of droplet ejection units 25A, 25B and 25C having the above-described construction are arranged such that positions P21 to P23 of respective ejection start points of those units are different from each other as viewed in the direction perpendicular to the scan direction. Further, in this embodiment, the plurality of droplet ejection units 25A, 25B and 25C having the above-described construction are arranged such that positions P24 to P26 of respective ejection end points of those units are also different from each other.

By employing the droplet ejection units 25A, 25B and 25C having the above-described construction such that, as shown in FIG. 9, the positions P21 to P23 of the ejection start points of those units and the positions P24 to P26 of the ejection end points are different from each other, it is possible to obtain not only similar advantages to those in the first embodiment, but also to eject a large number of droplets by one scan and to improve productivity. Also, the existing droplet ejection heads 22 can be employed in proper combinations in match with the object to be manufactured, and therefore adaptability for the object to be manufactured can be increased.

The droplet ejection units 25A, 25B and 25C can be individually applied to a common object to be manufactured (substrate). For example, the operation is performed such that, after processing the object to be manufactured using a droplet ejecting apparatus provided with the droplet ejection unit 25A, the object to be manufactured is set on a droplet ejecting apparatus provided with the droplet ejection unit 25B and then processed. Alternatively, the droplet ejection units 25A, 25B and 25C can be simultaneously applied to the object to be manufactured. For example, the plurality of droplet ejection units are all mounted into an integral structure, and droplets are ejected from those units at the same time in parallel.

While the droplet ejection units 25A, 25B and 25C have the ejection widths 25t1 to 25t3 equal to each other, the ejection widths 25t1 to 25t3 may be different from each other. In the latter case, the ejection widths 25t1 to 25t3 of the plurality of droplet ejection units 25A, 25B and 25C may be arranged to have similar relative positional relationships to those among the ejection widths of the plurality of droplet ejection heads 22 shown in FIGS. 4 to 6 representing the first embodiment. In other words, the ejection widths may be arranged to have the positional relationship in which the positions of the ejection start points and the positions of the ejection end points are both different from each other (corresponding to FIG. 4), or the positional relationship in which the positions of the ejection start points are the same, but the positions of the ejection end points are different from each other (corresponding to FIG. 5), or the positional relationship in which the positions of the ejection start points are different from each other, but the positions of the ejection end points are the same (corresponding to FIG. 6).

### ARRANGEMENT EXAMPLE 2

Arrangement Example 2 will be described below with reference to FIGS. 10 to 12. In Arrangement Example 2, as shown in FIG. 10, the plurality of droplet ejection heads 22 are arranged on a line in the direction (sub-scan direction Y) perpendicular to the scan direction. Then, a spacing is left between nozzles at the opposing ends of the adjacent droplet ejection heads 22 arranged as described above. Thus in Arrangement Example 2, unlike Arrangement Example 1, the nozzles 27 are not arranged so as to have a continuous total ejection width and the nozzle rows 28 in the individual droplet ejection heads 22, each having the ejection width t, are arranged with a spacing s left therebetween. As shown in the illustrated example, the spacing s is preferably equal to the ejection width t of the droplet ejection head 22. In addition, the plurality of droplet ejection heads 22 are mounted on the common sub-carriage 25 similarly to Arrangement Example 1.

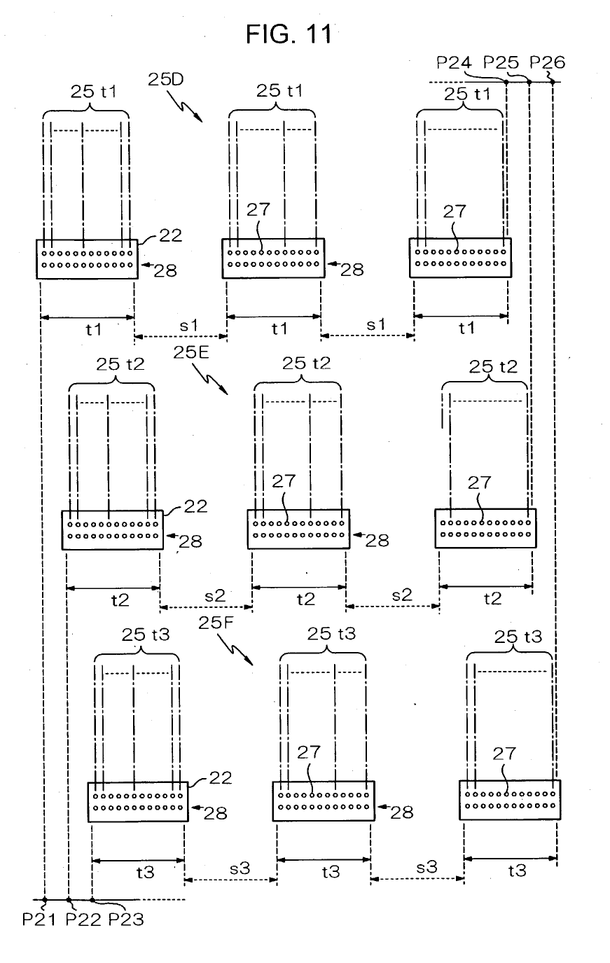

FIG. 11 shows relative positional relationships among a plurality of droplet ejection units 25D, 25E and 25F each constructed as shown in FIG. 10. In Arrangement Example 2, similarly to Arrangement Example 1, the plurality of droplet ejection units 25D, 25E and 25F have respectively ejection widths t1, t2 and t3 and spacings s1, s2 and s3. As shown in the illustrated example, the ejection widths t1, t2 and t3 may be set equal to each other and the spacings s1, s2 and s3 may be set equal to each other among the droplet ejection units. In the illustrated example, the numbers of the ejection widths and the spacings arranged in the direction perpendicular to the scan direction are also set equal to each other among the droplet ejection units. Further, positions P21 to P23 of the ejection start points are arranged to be different from each other among the plurality of droplet ejection units 25D, 25E and 25F. Likewise, positions P24 to P26 of the ejection end points in the plurality of droplet ejection units 25D, 25E and 25F are arranged to be different from each other.

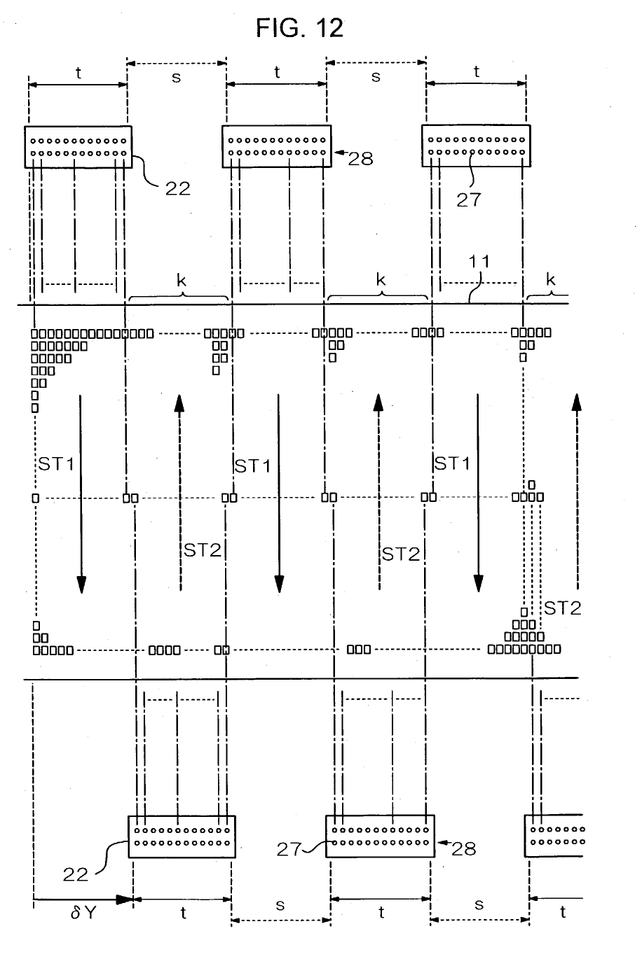

With the droplet ejection units 25D, 25E and 25F, since the spacing is left between the adjacent droplet ejection heads 22, a zone k corresponding to the spacing s remains not yet processed after a scan step ST1 (indicated by a downward arrow in FIG. 12) to scan an area 11 of the object to be manufactured (corresponding to a color-filter formed area described later) in the scan direction, as shown in FIG. 12. Subsequent to the scan step ST1, therefore, another scan step ST2 is performed after moving the droplet ejection units by δY=t=s in the direction perpendicular to the scan direction. In the illustrated example, the scan direction is reversed between the scan step ST1 and the scan step ST2. Hence, it is possible to perform the scan step ST1 in a going stroke in one direction and thereafter to perform the scan step ST2 in a return stroke in an opposite direction.

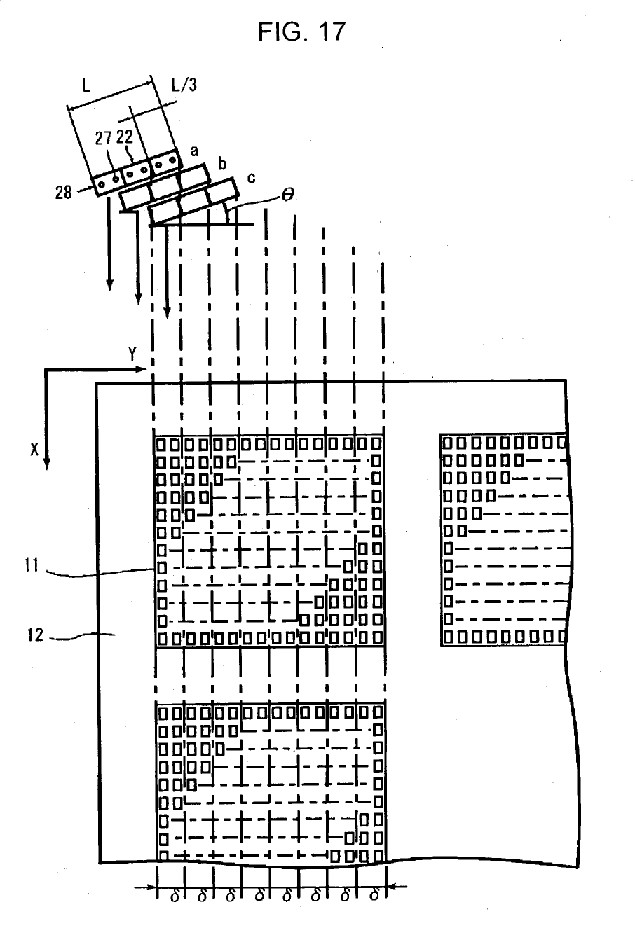

However, the scan step ST2 may be performed in the same direction as the scan step ST1. Also, when performing a later-described method (in which the scan step is repeated with a scan position shifted bit by bit in the sub-scan direction Y) as shown in FIG. 17, the object to be manufactured can be processed in the same manner although the number of necessary scan steps is increased.

### ARRANGEMENT EXAMPLE 3

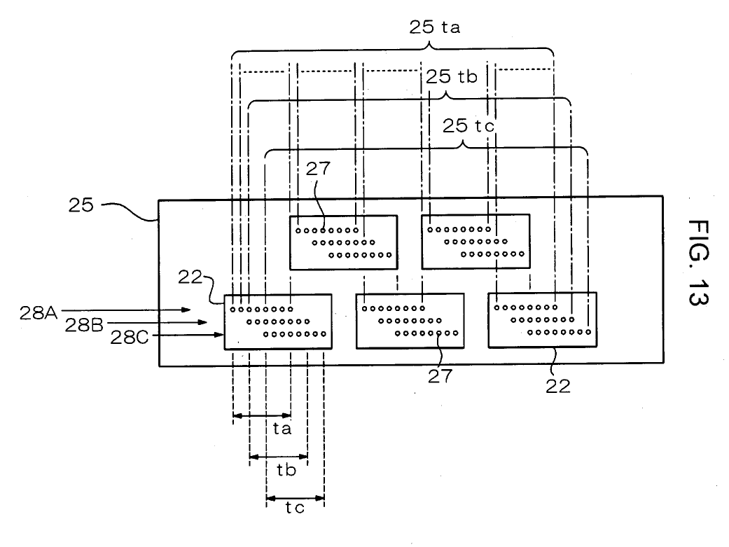

Arrangement Example 3 will be described below with reference to FIG. 13. In Arrangement Example 3, a droplet ejection head 22 having the same structure as that shown in FIG. 7 is employed. More specifically, the droplet ejection head 22 has a plurality of nozzle rows 28A, 28B and 28C arranged in a spaced relation in the scan direction and arranged in a mutually shifted relation in the direction perpendicular to the scan direction. In the illustrated example, as with the structure shown in FIG. 7(a), the nozzle rows 28A, 28B and 28C are arranged such that they have ejection widths ta, tb and tc and the respective positions of the ejection start and end points are both different from each other. Alternatively, the nozzle rows may be arranged such that their ejection widths ta, tb and tc are different from each other and the nozzle rows are formed in any of the positional relationships shown in FIGS. 7(b) to 7(d). In other words, the nozzle rows may be formed in the arrangement in which the positions of the ejection start points and the positions of the ejection end points are both different from each other (corresponding to FIG. 7(b)), or the arrangement in which the positions of the ejection start points are the same, but the positions of the ejection end points are different from each other (corresponding to FIG. 7(c)), or the arrangement in which the positions of the ejection start points are different from each other, but the positions of the ejection end points are the same (corresponding to FIG. 7(d)), while the ejection widths of the nozzle rows are different from each other.

Additionally, the droplet ejection heads 22 are mounted on the common sub-carriage 25 in Arrangement Example 3 as well.

As with Arrangement Example 1, looking at the droplet ejection heads 22 in the direction perpendicular to the scan direction, the heads 22 are arranged so as to locate in positions alternately shifted in the scan direction. On this occasion, relative positional relationships among the plurality of droplet ejection heads 22 are selected such that the nozzles rows 28A of the individual droplet ejection heads 22 are continuously arrayed in the direction perpendicular to the scan direction without gaps between them, the nozzles rows 28B are continuously arrayed in the same direction without gaps between them, and the nozzles rows 28C are continuously arrayed in the same direction without gaps between them. With such an array, this Arrangement Example provides one droplet ejection unit having ejection widths 25ta, 25tb and 25tc with the respective positions of the ejection start and end points being both different from each other. Alternatively, the positions of ones of the ejection start and end points may be different from each other, and the positions of the others of the ejection start and end points are the same.

In this Arrangement Example 3, since the plurality of nozzle rows 28A, 28B and 28C having the respective positions of the ejection start or end points, which are different from each other, are provided in each droplet ejection head 22, similar advantages to those in the above-described Arrangement Examples can be obtained just by scanning one unit on which a set of droplet ejection heads is mounted. The droplet ejection heads 22 in Arrangement Example 3 may be arranged on a line with a spacing between them like the one droplet ejection unit shown as Arrangement Example 2. With such a modification, similar advantages to those in the above-described Arrangement Examples can also be obtained by employing only one unit.

### ARRANGEMENT EXAMPLE 4

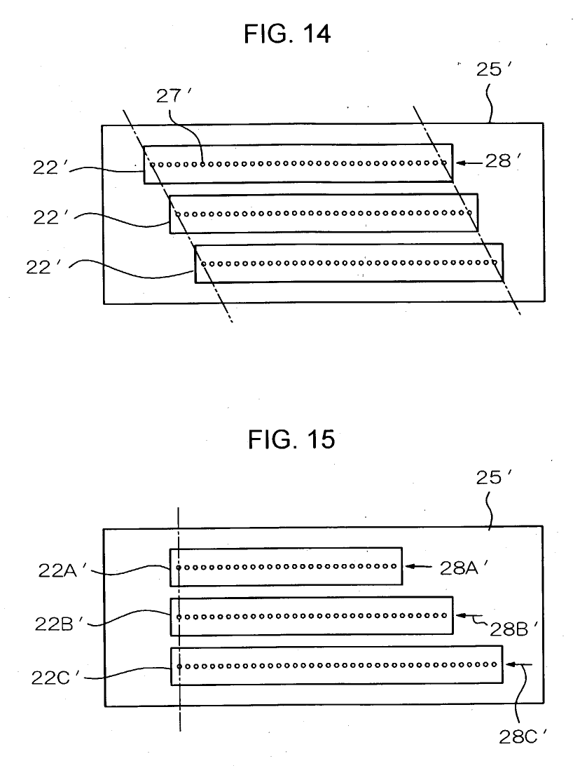

Arrangement Example 4 will be described below with reference to FIGS. 14 and 15. In this Arrangement Example 4, a plurality of droplet ejection heads 22′ are arranged in predetermined relative positional relationships similarly to the above-described Arrangement Examples 1 to 3, but the plurality of droplet ejection heads 22′ are formed to have the positions of the ejection start points or the positions of the ejection end points, which are different from each other.

More specifically, in an example shown in FIG. 14, the plurality of droplet ejection heads 22′ have all the same ejection width, but they are arranged at positions relatively shifted in the array direction of the nozzles 27 such that the positions of the ejection start points and the positions of the ejection end points are different from each other among the droplet ejection heads 22′. In an example shown in FIG. 15, nozzle rows 28A′, 28B′ and 28C′ provided in a plurality of droplet ejection heads 22A′, 22B′ and 22C′ have different ejection widths from each other and are arranged such that the positions of the ejection start points are all the same, but the positions of the ejection end points are different from each other. In the example of FIG. 15, the nozzle rows may be arranged such that the positions of the ejection start points are different from each other, but the positions of the ejection end points are all the same, or the positions of the ejection start points and the positions of the ejection end points are both different from each other. This Arrangement Example 4 can also provide similar advantages to those in the above-described Arrangement Examples because the positions of the ejection start points or the positions of the ejection end points are different from each other among the plurality of droplet ejection heads.

According to the present invention, as described above, when ejecting droplets from a plurality of nozzle arrays each having a plurality of droplet ejection nozzles by relatively scanning the plurality of nozzle arrays in the scan direction, respective positions of ejection start or end points of the nozzle arrays are made different from each other. For example, as with the first embodiment, the end positions of a plurality of droplet ejection heads having respective nozzle rows are set different from each other, or the end positions of a plurality of nozzle rows provided in one droplet ejection head are set different from each other. Also, as with the above-described Arrangement Examples, when a plurality of droplet ejection heads are relatively fixed in predetermined positional relationships to constitute an integral droplet ejection unit, a plurality of droplet ejection units can be employed and arranged such that respective positions of ejection start or end points being are different from each other among the plurality of droplet ejection units. Alternatively, the plurality of droplet ejection heads provided in one droplet ejection unit can be arranged such that respective positions of the ejection start or end points of the plurality of droplet ejection heads are different from each other. In addition, a plurality of nozzle rows can be provided in each of the plurality of droplet ejection heads in one droplet ejection unit and arranged such that respective positions of the ejection start or end points of the plurality of nozzle rows are different from each other.

[Third Embodiment]

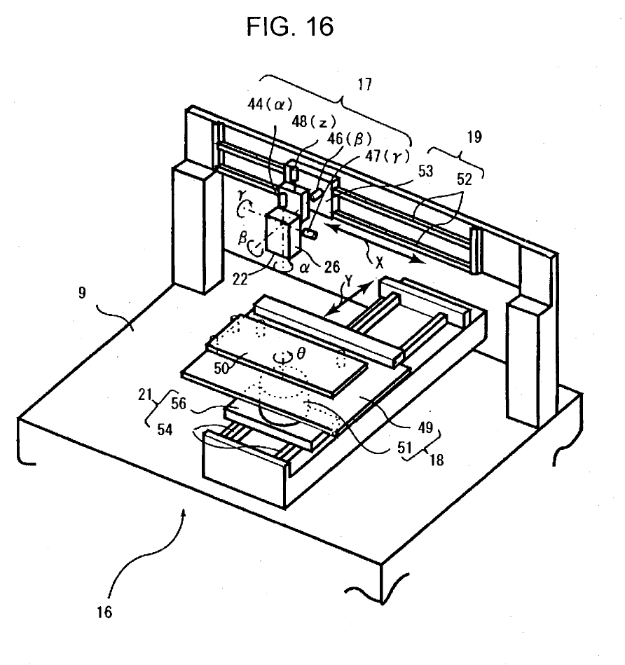

A third embodiment represents a liquid material ejecting apparatus having a droplet ejection head, schematically shown in FIG. 16, in which a plurality of liquid materials are successively ejected while relatively scanning the droplet ejection head or a substrate, and nozzle rows are provided in the droplet ejection head such that respective positions of ejection start and/or end points for the plurality of liquid materials are different from each other.

In the following, a description regarding similar points to those in the first embodiment is omitted, and a description is made of mainly different points in the liquid material ejecting apparatus of the third embodiment.

1. Ejection Mechanism Scheme

The third embodiment can also employ a similar scheme to that in the first embodiment, and therefore a further description is omitted here.

2. Liquid Materials

The third embodiment can also employ similar liquid materials to those in the first embodiment, and therefore a further description is omitted here.

3. Ejecting Apparatus

An ejecting apparatus 16 of the third embodiment preferably comprises, as shown in FIG. 16, a head unit 26 including a droplet ejection head 22, a head position controller 17 for controlling the position of the head 22, a substrate position controller 18 for controlling the position of a motherboard, a main scan driver 19 for moving the head 22 for main scan in the scan direction (main scan direction X) relative to the motherboard, a sub-scan driver 21 for moving the head 22 for sub-scan in a direction (sub-scan direction Y) crossing the scan direction relative to the motherboard, a substrate supply apparatus (not shown) for supplying the motherboard to a predetermined work position in the droplet ejecting apparatus 16, and a control device (not shown) for supervising overall control of the droplet ejecting apparatus 16.

Structures and operations of the ejecting apparatus 16 will be described below primarily in connection with the case of manufacturing a color filter.

(1) Droplet Ejection Head

Construction

In the third embodiment, the head 22 preferably has an internal structure shown in FIGS. 1(a) and 1(b).

More specifically, the head 22 preferably comprises a nozzle plate 29 made of, e.g., stainless steel, a vibrating plate 31 arranged to face the nozzle plate 29, and a plurality of partition members 32 for joining the nozzle plate 29 and the vibrating plate 31 to each other. A plurality of material chambers 33 and a liquid reservoir 34 are formed between the nozzle plate 29 and the vibrating plate 31 by the partition members 32. The plurality of material chambers 33 and the liquid reservoir 34 are communicated with each other through passages 38.

Material supply holes 36 are formed in the vibrating plate 31 at appropriate positions, and a material supply apparatus 37 is connected to the material supply holes 36. The material supply apparatus 37 supplies, to the material supply holes 36, one of filter element materials (M), e.g., a filter element material (M) corresponding to R ones of RGB pixels or a filter element material (M) corresponding to Y ones of YMC pixels, in the liquid form. The supplied filter element material is filled in the liquid reservoir 34 and further filled in the material chambers 33 through the passages 38.

Also, a row of nozzles 27 for ejecting the filter element material (M) in the form of a jet from the material chambers 33 are provided in the nozzle plate 29. On the rear surface of the vibrating plate 31 which defines the material chambers 33, material pressurizing members 39 are attached corresponding to the material chambers 33. As shown in FIG. 1(b), each of the material pressurizing members 39 preferably comprises a piezoelectric device 41 and a pair of electrodes 42a, 42b holding the piezoelectric device 41 between them.

Upon electric power supplied to the electrodes 42a and 42b, the piezoelectric device 41 is flexibly deformed to project outward as indicated by an arrow C, and develops the function of increasing the volume of the corresponding material chamber 33. This enables the filter element material (M) to flow into the material chamber 33 from the liquid reservoir 34 through the passage 38 in amount corresponding to the increased volume of the material chamber 33.

Then, upon release of the electric power supplied to the piezoelectric device 41, the piezoelectric device 41 and the vibrating plate 31 are both returned to their original shapes. Correspondingly, the material chamber 33 is returned to the original volume and the pressure of the filter element material (M) in the material chamber 33 is increased. As a result, the filter element material (M) is ejected from the nozzle row 27 toward a motherboard 12 in the form of a droplet 8. Relationship between Droplet Ejection Head and Nozzle Row for Liquid Materials

In the third embodiment, as shown in FIG. 7, the nozzle rows 27 corresponding to a plurality of liquid materials are preferably arranged on one droplet ejection head 22 as desired.

When providing a nozzle row for a first liquid material, a nozzle row for a second liquid material, and a nozzle row for a third liquid material, for example, these nozzle rows for the three liquid materials are arranged in one droplet ejection head in three lines corresponding to the three liquid materials. Alternatively, the first to three nozzle rows are continuously arranged in one droplet ejection head so as to lie on a horizontal line, or they are arranged in a combined pattern of those arrays.

With those arrangements, just by preparing one set of droplet ejection head and driving device, the applied material can be obtained such that respective positions of ejection start and/or end points for the plurality of liquid materials are not overlapped with each other. Accordingly, an ejecting apparatus having a simple structure as a whole is provided which can produce the applied material while ensuring that the respective positions of the ejection start or end points for the plurality of liquid materials are not or less overlapped with each other on the substrate.

Also, with those arrangements, because only one droplet ejection head is employed, there is no risk that droplet ejection heads contact or strike against each other during the operation, even when the plurality of liquid materials are ejected at the same time.

The plurality of nozzle rows provided on one droplet ejection head are preferably arranged at essentially the same interval. With this arrangement, the applied material having a regular predetermined pattern can be formed with high accuracy.

Also, preferably, the droplet ejection head is formed into a substantially elongate rectangular shape, and the plurality of nozzle rows are arranged parallel to the edges of long sides of the rectangular head. With this arrangement, the size of the droplet ejection head can be reduced, and the applied material having a regular predetermined pattern can be formed with high accuracy.

Further, preferably, the shapes and the numbers of the plurality of nozzle rows provided on one droplet ejection head corresponding to the plurality of liquid materials are essentially the same and the same value. With this arrangement, the plurality of nozzle rows can be easily arranged in the droplet ejection head, the plurality of liquid materials can be ejected in more uniform amount, and the applied material having a regular predetermined pattern can be formed with high accuracy.

In the third embodiment, it is also preferable that, as shown in FIGS. 3 to 6, the nozzle rows 27 corresponding to the plurality of liquid materials are provided respectively in the plurality of droplet ejection heads 22 in a one-to-on corresponding relation. When providing the nozzle row for the first liquid material, the nozzle row for the second liquid material, and the nozzle row for the third liquid material, for example, a first droplet ejection head, a second droplet ejection head and a third droplet ejection head are disposed corresponding to these nozzle rows for the three liquid materials.

With that arrangement, just by preparing a plurality of droplet ejection heads, which have widths essentially equal to each other, corresponding to the plurality of liquid materials, an ejecting apparatus is provided which can produce the applied material while ensuring that the respective positions of the ejection start or end points for the plurality of liquid materials are not overlapped with each other on the substrate.

Also, because the plurality of droplet ejection heads are employed, those heads can be individually operated corresponding to the plurality of liquid materials. Therefore, the respective positions of the ejection start or end points for the plurality of liquid materials can be more easily adjusted.

In the case of providing the nozzle rows corresponding to the plurality of liquid materials in a one-to-one relation to the plurality of droplet ejection heads, as in the case of providing one droplet ejection head, the plurality of nozzle rows are preferably arranged at essentially the same interval. Also, preferably, the droplet ejection heads are each formed into a substantially elongate rectangular shape, and the plurality of nozzle rows are arranged parallel to the edges of long sides of the rectangular heads. Further, preferably, the shapes and the numbers of the plurality of nozzle rows are essentially the same and the same value.

Moreover, as shown in FIG. 17, the droplet ejection head 22 is preferably arranged in an inclined posture. In other words, the droplet ejection head 22 is preferably arranged so as to lie in a direction obliquely crossing the direction (sub-scan direction Y) perpendicular to the head moving direction (main scan direction X). In practice, an inclination angle (θ) shown in FIG. 17 is preferably set to a value within the range of 1 to 60°, more preferably within the range of 10 to 50°, and even more preferably within the range of 20 to 45°.

With such an arrangement, an actual interval (denoted by 6 in FIG. 17), over which one liquid material is ejected, can be made smaller than the interval (denoted by L/3 in FIG. 17) of the nozzle row corresponding to one liquid material. Accordingly, a finer drawing pattern can be obtained in, e.g., a color filter shown in FIG. 17 formed by the applied material.

Furthermore, with such an arrangement, even when a plurality of droplet ejection heads are provided, it is possible to prevent the adjacent droplet ejection heads from interfering with each other. Consequently, the unit size of the droplet ejection heads can be reduced.

In addition, with such an arrangement, even when the substrate size is changed to some extent, the liquid materials can be applied to the overall substrate surface by changing the cross angle of the droplet ejection head as required. More specifically, when the substrate size is relatively large, the plurality of liquid materials can be applied onto the overall substrate surface by setting the inclination angle θ to a relatively small value. On the other hand, even when the substrate size is relatively small, the plurality of liquid materials can be applied to the overall substrate surface by setting the inclination angle θ to a relatively large value without replacing the droplet ejection head.

(2) Substrate Position Controller and Substrate Supply Apparatus Substrate Position Controller

In the third embodiment, the substrate position controller 18 shown in FIG. 16 preferably comprises a table 49 on which a motherboard is placed, and a θ motor 51 for rotating the table 49 in a plane as indicated by an arrow θ.

Also, the main scan driver 19 shown in FIG. 16 preferably comprises a pair of X guide rails 52 extending in the main scan direction X, and an X slider 53 with a pulse-driven linear motor built therein. With such a construction, upon operation of the built-in linear motor, the X slider 53 can be moved parallel to the X guide rails 52 in the main scan direction.

Further, the sub-scan driver 21 shown in FIG. 16 preferably comprises a pair of Y guide rails 54 extending in the sub-scan direction Y, and a Y slider 56 with a pulse-driven linear motor built therein. With such a construction, upon operation of the built-in linear motor, the Y slider 56 can be moved parallel to the Y guide rails 54 in the sub-scan direction.

Substrate Supply Apparatus

In the third embodiment, it is preferably that, though not shown, a substrate supply apparatus is provided and the substrate supply apparatus comprises a substrate containing unit for containing motherboards and a robot for carrying the motherboard.

The robot preferably comprises a base placed on an installation surface such as a floor or a ground, a lifting shaft vertically movable relative to the base, a first arm rotating about the lifting shaft, a second arm rotating relative to the first arm, and an absorption pad provided on the underside of a fore end of the second arm.

(3) Control Unit

In the third embodiment, a control device serving as a control unit preferably comprises a computer main unit incorporating a processor, a keyboard as an input device, and a CRT (Cathode-Ray Tube) display as a display device.

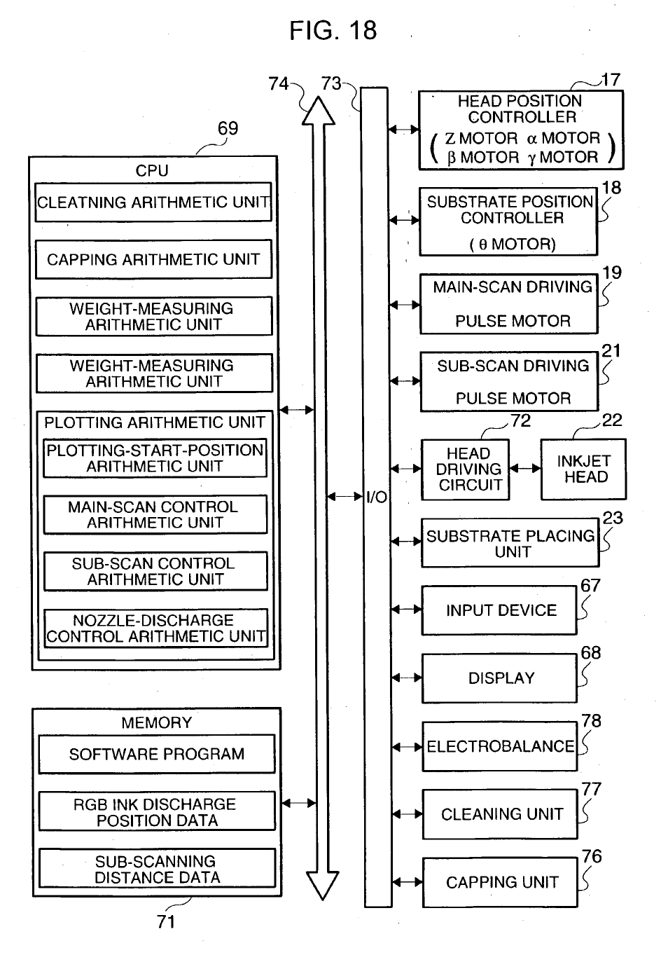

As shown in FIG. 18, the processor preferably comprises a CPU (Central Processing Unit) 69 for executing computation and processing, and a memory for storing a variety of information, i.e., an information storage medium 71. The CPU 69 performs control to eject inks, i.e., filter element materials 13 (see FIG. 19), in predetermined positions on the motherboard in accordance with program software stored in the memory, i.e., the information storage medium 71.

Various components shown in FIG. 16, i.e., the head position controller 17, the substrate position controller 18, the main scan driver 19, the sub-scan driver 21, and a head driving circuit for driving the piezoelectric device 41 in the head 22, are preferably connected to the CPU 69 via an input/output interface 73 and a bus 74, as shown in FIG. 18.

Further, for the sake of easier control, a substrate supply apparatus 23, an input device 67, a CRT display 68, an electronic balance 78, a cleaning device 77, and a capping device 76 are preferably connected to the CPU 69 via the input/output interface 73 and the bus 74.

As practical function realizing sections, as shown in FIG. 18, the CPU 69 preferably comprises a cleaning processing section for executing computation to realize a cleaning process, a capping processing section for realizing a capping process, a weight measurement processing section for executing computation to realize weight measurement using the electronic balance, and a drawing processing section for executing computation to make drawing of a material pattern through droplet ejection.

The drawing processing section preferably comprises a drawing start position processing section for setting the head 22 to an initial position for drawing, a main scan control processing section for executing computation of scan control to move the head 22 at a predetermined speed in the main scan direction X, a sub-scan control processing section for executing control computation to shift the motherboard by a predetermined sub-scan amount in the sub-scan direction Y, and a nozzle ejection control processing section for executing control computation to determine whether any of the plurality of nozzle rows 27 in the head 22 is to be operated to eject the ink, i.e., the filter element material.

(4) Other Component Devices

In the third embodiment, the capping device and the cleaning device are preferably disposed at a position on one side of the sub-scan driver under a locus along which the head is driven by the main scan driver to move for main scan. Also, the electronic balance is preferably disposed at a position on the other side of the sub-scan driver.

The cleaning device is a device for cleaning the head. The electronic balance is a device for measuring, per nozzle, the weight of material droplets ejected from the individual nozzle rows in the head. The capping device is a device for preventing the nozzle rows from being dried when the head is in a standby state.

In the vicinity of the head, a camera for the head is preferably disposed to be movable together with the head for easier positioning of the head. Also, a camera for the substrate is preferably supported on a support device provided on a base and disposed at a position where the camera is able to take an image of the motherboard.

[Fourth Embodiment]

A fourth embodiment represents a color filter manufacturing method featured in that a plurality of color filter materials are successively ejected from corresponding nozzle rows, and respective positions of ejection start and/or end points for the plurality of color filter materials are set different from each other.

In the following, a description regarding similar points to those in the first to third embodiments is omitted, and a description is made of mainly different points in the color filter manufacturing method and the color filter of the fourth embodiment.

1. Color Filter Manufacturing Method

(1) Formation of Partition Wall

FIG. 19 schematically shows a method of manufacturing a color filter 1 in sequence of successive steps. In the fourth embodiment, a partition wall 6 is first formed on the surface of a motherboard 12 in a lattice pattern, as viewed in the direction of an arrow B, with a resin material not transparent to light.

Lattice holes 7 in the thus-formed lattice pattern correspond to areas in which filter elements 3 are to be formed later, i.e., filter-element formed areas. To obtain satisfactory resolution, therefore, planar dimensions, as viewed in the direction of an arrow B, of each of the filter-element formed areas 7 defined by the partition wall 6 are preferably set to, for example, 30 μm×100 μm.

Also, the partition wall 6 preferably has not only the function of preventing spilling-out of a filter element material 13 supplied in the liquid form to the filter-element formed areas 7, but also the function of a black mask.

For the purposes of forming the partition wall 6 with high accuracy and increasing the mechanical strength thereof, the partition wall 6 is preferably formed using, for example, photolithography. It is also preferable to heat the filter element material 13 using a heater, an oven or the like, as required, for hardening it under heating.

(2) Formation of Filter Elements

Then, in the fourth embodiment, a plurality of filter element materials corresponding to, e.g., RGB pixels or YMC pixels are successively ejected from corresponding nozzle rows, and respective positions of ejection start and/or end points for the plurality of filter element materials (color filter materials) are set different from each other.

More specifically, as shown in FIG. 19(b), droplets 8 of the filter element materials 13 corresponding to, e.g., RGB pixels or YMC pixels are supplied to the filter-element formed areas 7 while ensuring that the respective positions of the ejection start and/or end points are different from each other. As a result, the filter-element formed areas 7 are filled with the filter element materials 13, whereby the filter element is formed.

As preferred means for changing the positions of the ejection start points and the positions of the ejection end points, eight kinds of modes listed in Table 1, described above in connection with the first embodiment, taking into account the number and the ejection widths of the droplet ejection heads.

After the filter-element formed areas 7 have been filled with the filter element materials 13 in predetermined amount, the motherboard 12 is heated to, e.g., about 70° C. using a heater so that the solvent of the filter element materials 13 is evaporated.

With the evaporation of the solvent, as shown in FIG. 19(c), the volume of the filter element materials 13 is reduced and the surfaces of the filter element materials 13 are flattened. On the other hand, when the volume of the filter element materials 13 is too much reduced, it is preferable to repeat the steps of supplying the droplets 8 of the filter element materials 13 and heating the droplets 8 until a film thickness sufficient for the color filter 1 is obtained. In the manufacturing method of FIG. 19, the above steps are repeated three times, for example, as shown.

(3) Heat Treatment and Formation of Protective Film

Then, heat treatment is preferably performed at a predetermined temperature for a predetermined time for fully drying the formed filter elements 3.

Thereafter, as shown in FIG. 19(d), a protective film 4 is preferably formed using any suitable known method such as spin coating, roll coating, dipping, or ink jetting. The protective film 4 is formed to protect the filter elements 3, etc. and to flatten the surface of the color filter 1.

2. Color Filter

(1) Construction

The color filter 1 in the fourth embodiment is preferably constructed such that the plurality of filter elements 3 are formed in a dot pattern, e.g., in the form of a dot matrix in this embodiment, on the surface of a square substrate 2 made of glass, plastic or the like.

The filter elements 3 are separated by the partition wall 6 that is formed in a lattice pattern using a resin material not transparent to light, and are formed by filling the filter element materials (color filter materials) in a plurality of square areas arrayed in the form of a dot matrix.

Also, preferably, the filter elements 3 are each formed of one of the filter element materials corresponding to one of three colors, e.g., R (red), G (green) and B (blue), or Y (yellow), M (magenta) and C (cyan), and the filter elements 3 for each color are arranged in a predetermined array.

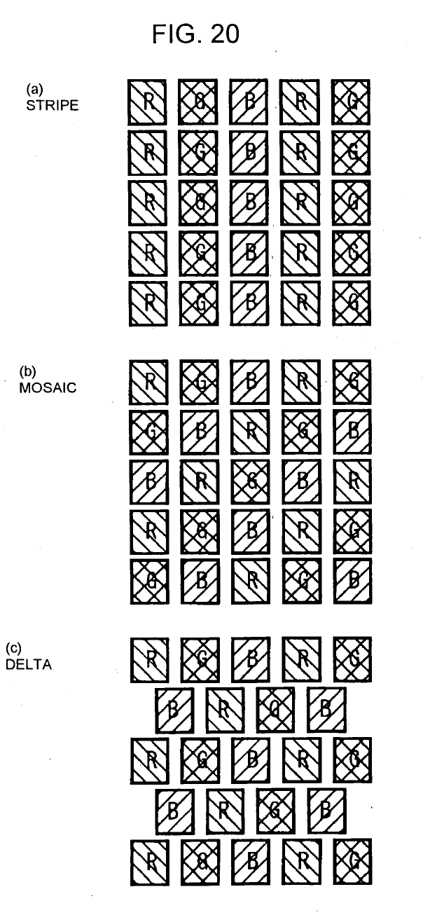

As one preferable example of the array of the filter elements 3, FIG. 20(a) shows the so-called stripe array in which each vertical column of a matrix is entirely formed of the filter elements 3 of the same color. As another preferable example, FIG. 20(b) shows the so-called mosaic array in which arbitrary sets of three filter elements 3 linearly arranged in the vertical and horizontal directions have three colors in sequence so as to constitute RGB pixels. As still another preferable example, FIG. 20(c) shows the so-called delta array in which the filter elements 3 are arranged in a staggered pattern and arbitrary sets of three adjacent filter elements 3 have three colors in sequence so as to constitute RGB pixels or YMC pixels.

In the fourth embodiment, the size of the color filter 1 is not limited to a particular value, but the color filter is preferably formed into a rectangular shape with its diagonal line having a length of, e.g., 1.8 inch (4.57 cm). The size of one filter element 3 is also not limited to a particular value, but each filter element can be formed into a rectangular shape with a horizontal length of 10 μm to 100 μm and a vertical length of 50 μm to 200 μm, for example. Further, the interval between the filter elements 3, i.e., the so-called element-to-element pitch, can be set to, for example, 50 μm or 75 μm.

When the color filter 1 of the fourth embodiment is employed in a liquid crystal display, etc. as an optical element for full-color display, three filter elements 3 corresponding to RGB pixels or YMC pixels are preferably formed as one unit that constitutes one pixel dot. Then, full-color display is preferably performed by causing light emitted from the liquid crystal display, etc. to selectively pass one or any combination of two or more of the RGB pixels or the YMC pixels in one pixel dot.

On that occasion, preferably, the partition wall 6 formed of a resin material essentially not transparent to light serves as a black mask, thereby preventing color mixing and improving contrast.

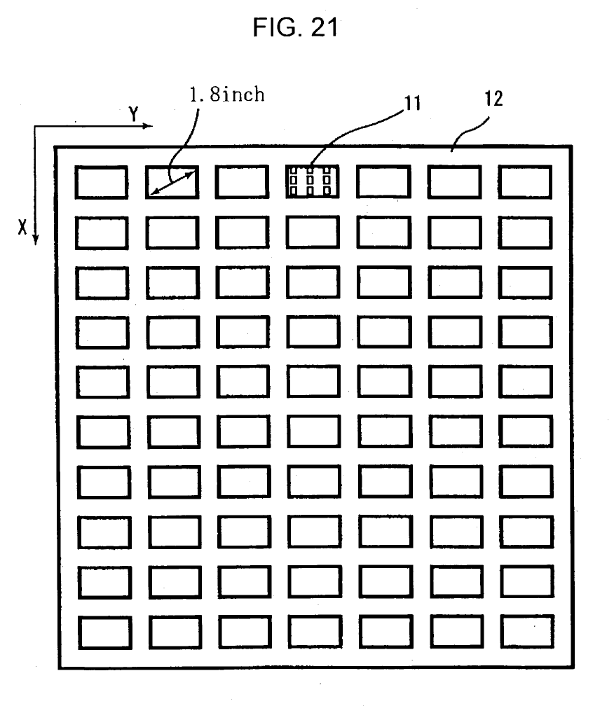

In addition, the individual color filters 1 are each preferably cut out from a large-sized substrate, e.g., the motherboard 12 shown in FIG. 21, because the manufacturing cost is reduced and the economical efficiency is increased.

More specifically, in each of a plurality of color-filter formed areas 11 set in the motherboard 12, patterns corresponding to one color filter 1 are formed on the surface of the filter-element formed area 11. Then, preferably, cut grooves are formed around each of the color-filter formed areas 11, and the motherboard 12 is cut along the grooves. As a result, a color filter board including the color filter 1 formed on each cut substrate 2 (see FIG. 19(a)) is obtained.

(2) Position of Absorption Peaks of Light Transmittance

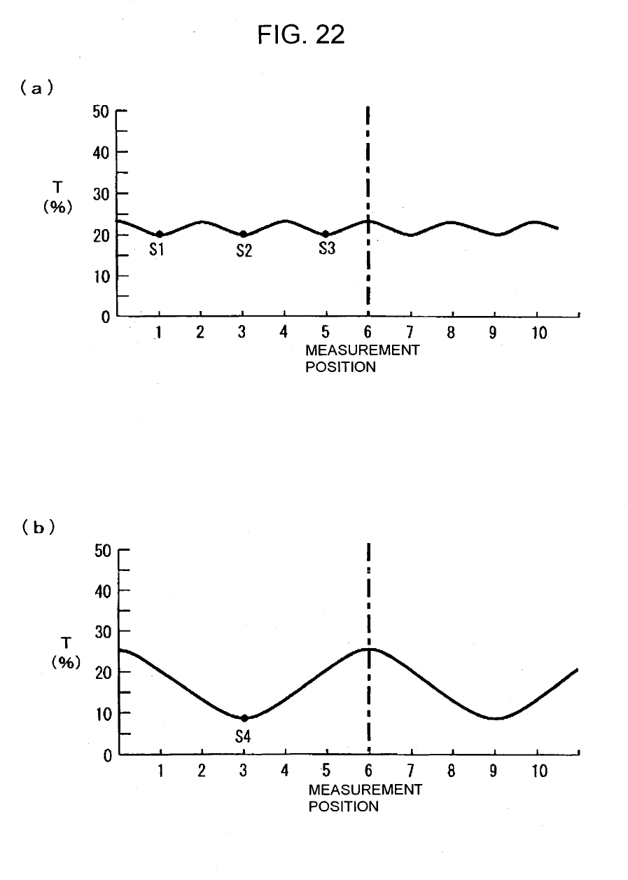

In the color filter 1 of the fourth embodiment, as shown in FIG. 22(a), positions (S1, S2, S3) of absorption peaks of light transmittance corresponding to the plurality of filter element materials (color filter materials) are preferably made different from each other within the application width of the droplet ejection head.

In FIG. 22(a), the horizontal axis represents positions of measurement. The measurement positions until the sixth position from the first one along the horizontal axis correspond to the application width of the droplet ejection head per scan. The vertical axis represents light transmittance T (%) of the color filter 1 and indicates a value measured by a brightness meter.

FIG. 22(b) shows, for comparison, a measurement result of a conventional color filter, i.e., a measurement result of the case in which respective positions (S4) of absorption peaks of light transmittance corresponding to the plurality of filter element materials are coincident with each other within the application width of the droplet ejection head.

By causing the light transmittance to have different peak positions for the plurality of filter element materials, it is possible to reduce variations in distribution of the film thickness in the planar direction, and hence to obtain a color filter having more uniform light transmittance characteristics, etc. in the planar direction. Such an arrangement also contributes to lessening color mixing possibly occurred at the boundary of adjacent applied regions.

The positions (S1, S2, S3) of absorption peaks of light transmittance corresponding to the plurality of filter element materials can be made different from each other just by adjusting, e.g., the end positions of the nozzle row such that the positions of the ejection start points or the positions of the ejection end points are changed. In other words, the plurality of filter element materials, e.g., filter element materials corresponding to RGB pixels, are less overlapped with each other and avoided from being applied in the ejection start points or the ejection end points corresponding to the ends of the applied region. Thus, the thickness of filter element materials is relatively uniformly distributed in the planar direction, and a color filter having more uniform light transmittance characteristics, etc. can be obtained.

3. Modification of Color Filter Manufacturing Apparatus

As a modification of the color filter manufacturing apparatus of the fourth embodiment, it is also preferable that, unlike the above-described construction, the main scan is performed with movement of the motherboard 12 and the sub-scan is performed with movement of the head 22.

In the fourth embodiment, it is further preferable to relatively move at least one of the head 22 and the motherboard 12, for example, by moving the motherboard 12 without moving the head 22 or moving both of the head 22 and the motherboard 12 relative to each other in opposed directions, such that the head 22 is relatively movable along the surface of the motherboard 12.

While the nozzle row 27 is preferably arranged in two rows on the head 22 to lie substantially on a line substantially at an equal interval, the number of the nozzle rows is not limited to two. For example, it is also preferable that three or more nozzle rows are arranged in a zigzag pattern at intervals not equal to each other.

4. Example of Usage of Color Filter

Preferably, a liquid crystal display is constructed using the color filter obtained as described above.

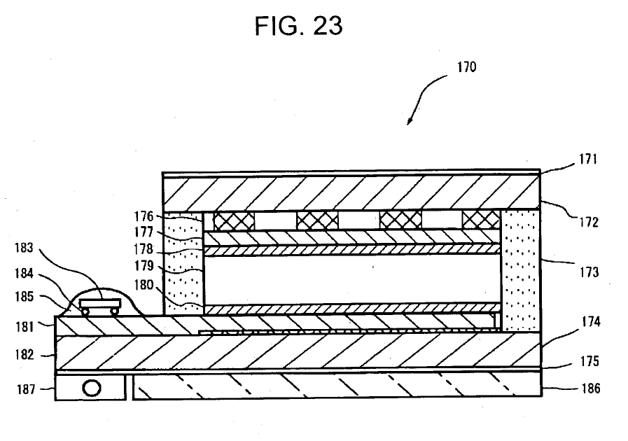

Although the construction and the manufacturing method of the liquid crystal display can be the same as those generally known, a liquid crystal display 170 shown in FIG. 23 is one preferable example. More specifically, the liquid crystal display 170 is preferably of a structure in which a first deflecting plate 175, a first substrate 174, a reflecting film 182, a first electrode 181, a first orientation plate 180, a liquid crystal 179, a second orientation plate 178, a second electrode 177, a color filter 176, a second substrate 172, and a first deflecting plate 171 are successively formed in this order from below and the surroundings of the multilayered laminate is sealed off by a sealing material 173. Then, full-color display is preferably realized by operating the liquid crystal 179 with a drive IC 183, which is mounted around the liquid crystal display 170, according to the single matrix passive method, the active method using TFD (Thin Film Diode) devices as switching devices, the active method using TFT (Thin Film Transistor) devices as switching devices, etc. More preferably, backlights 186, 187 are disposed under the first deflecting plate 175 for the purpose of obtaining a sharper image, etc.

Furthermore, the liquid crystal display 170 may be constructed of the transreflective type as shown in FIG. 23, or the transmissive type including a light transmissive area in the substrate, or the full-reflective type.

[Fifth Embodiment]

A fifth embodiment represents an electroluminescence device manufacturing method using a droplet ejection head, in which a plurality of electroluminescence materials are successively ejected from corresponding nozzle rows, and respective positions of ejection start and/or end points for the plurality of electroluminescence materials are set different from each other.

In the following, a description regarding similar points to those in the first to fourth embodiments is omitted, and a description is made of mainly different points in the electroluminescence device manufacturing method and a manufactured electroluminescence device.

1. Electroluminescence Device Manufacturing Method

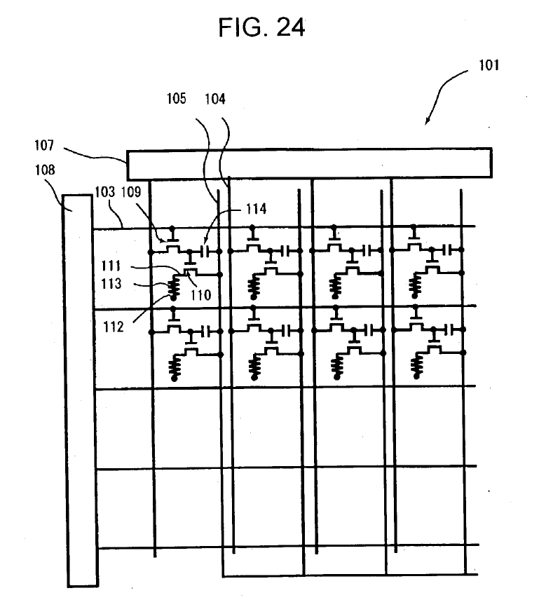

A description is now made of successive steps for manufacturing an active matrix electroluminescence display having a driving circuit schematically shown in FIG. 24.

(1) Pretreatment

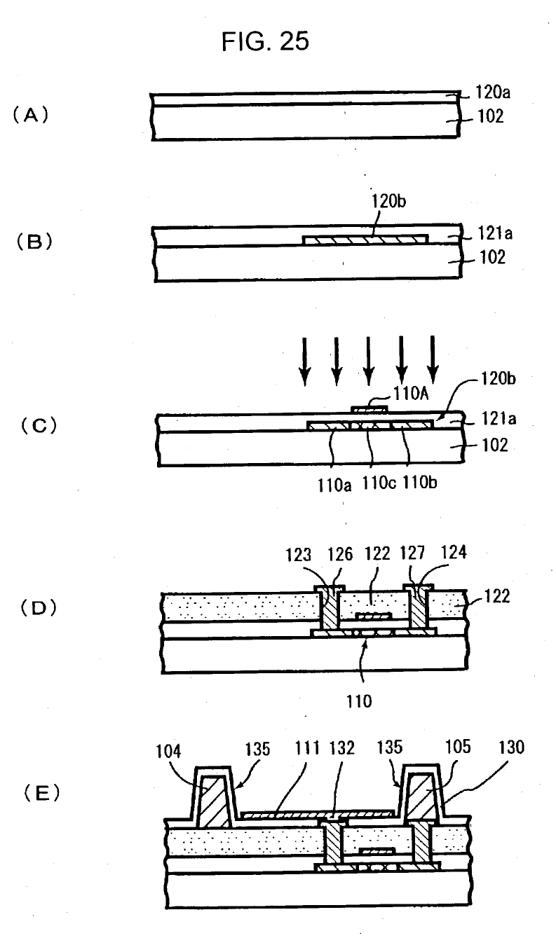

First, as shown in FIG. 25(A), an underlying protective film (not shown) made of a silicon oxide film is preferably formed on a transparent display board 102 by the plasma CVD (Chemical Vapor Deposition) process using, as a material gas, tetraethoxysilane (TEOS) or oxygen gas, for example.

In the above step, the thickness of the underlying protective film is preferably set to a value within the range of about 2,000 to 5,000 angstroms.

Then, the temperature of the display board 102 is set to about 350° C., and a semiconductor film 120a made of an amorphous silicon film is formed on the underlying protective film by the plasma CVD process. At this time, the thickness of the silicon film is preferably set to a value within the range of about 300 to 700 angstroms.

Thereafter, the semiconductor film 120a is preferably subjected to a crystallizing step, such as laser annealing or the solid epitaxial process, so that the semiconductor film 120a is crystallized into a poly-silicon film.

(2) Formation of TFT

Then, in the fifth embodiment, the semiconductor film 120a is patterned to form an island-like semiconductor film 120b, as shown in FIG. 25(B).

On the surface of the display board 102 on which the semiconductor film 120b is formed, a gate insulating film 121a made of a silicon oxide or nitride film is formed by the plasma CVD process using, as a material gas, TEOS or oxygen gas, for example. At this time, the thickness of the gate insulating film is preferably set to a value within the range of about 600 to 1500 angstroms.

While the semiconductor film 120b serves as channel, source and drain areas of a current thin-film transistor 110, another semiconductor film (not shown) is also formed at a different sectional position to serve as channel, source and drain areas of a switching thin-film transistor 109. In other words, in the manufacturing steps shown in FIG. 25, two kinds of transistors, i.e., the switching thin-film transistor 109 and the current thin-film transistor 110, are formed at the same time. However, since the two kinds of transistors are formed through the same sequence, the following description is made of only the current thin-film transistor 110, and a description of the switching thin-film transistor 109 is omitted here.

Subsequently, as shown in FIG. 25(C), an electrically conductive film of, e.g., aluminum or tantalum is formed by the sputtering process and then subjected to patterning to form a gate electrode 110A.

In this state, source and drain areas 110a, 110b are preferably formed in the semiconductor film 120b through self-alignment with respect to the gate electrode 110A by injecting an impurity, e.g., phosphorus ions at high temperature. A portion in which the impurity has not been introduced serves as a channel area 110c.

Then, as shown in FIG. 25(D), after forming an inter-layer insulating film 122, contact holes 123, 124 are formed through the inter-layer insulating film 122, and relay electrodes 126, 127 are formed respectively in the contact holes 123, 124 in the buried form.

Further, as shown in FIG. 25(E), a signal line 104, a common power supply line 105, and a scan line 103 (not shown in FIG. 25) are formed on the inter-layer insulating film 122.

Then, preferably, an inter-layer insulating film 130 is formed so as to cover the upper surfaces of the lines, and a contact hole 132 is formed at a position corresponding to the relay electrode 126. After forming an ITO film so as to bury the contact hole 132, the ITO film is patterned to form a pixel electrode 111, which is electrically connected to the source and drain areas 110a, 110b, at a predetermined position surrounded by the signal line 104, the common power supply line 105, and the scan line 103.

(3) Ejection of Electroluminescence Materials

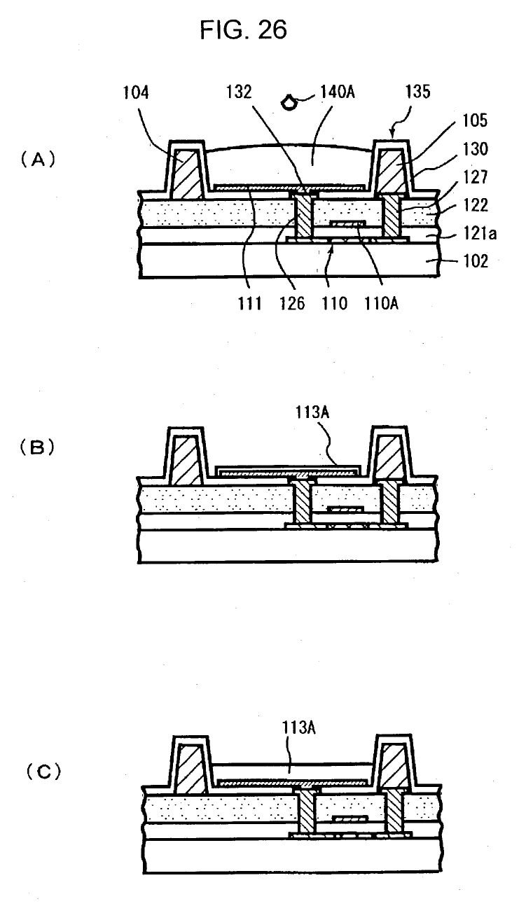

Subsequently, in the fifth embodiment, a plurality of electroluminescence materials are ejected onto the display board 102 which has been subjected to the pretreatment, as shown in FIG. 26.

More specifically, the plurality of electroluminescence materials are successively ejected from corresponding nozzle rows, and when ejecting the plurality of electroluminescence materials, positions of both or one ends of the nozzle rows, for example, are shifted in one- or two-dimensional directions so that respective positions of ejection start and/or end points for the plurality of electroluminescence materials are different from each other.

By forming luminous layers of the electroluminescence materials as described above, an electroluminescence display can be constructed in which the ejection start points and the ejection end points for the plurality of liquid materials are not or less overlapped with each other, and more uniform electroluminescence characteristics, e.g., smaller color changes due to differences in film thickness, are obtained in the planar direction.

As shown in FIG. 26(A), with the upper surface of the display board 102, which has been subjected to the pretreatment, being faced upward, an electroluminescence material 140A, e.g., polyphenylene vinylene, 1,1-bis-(4-N, N-ditolylaminophenyl)cyclohexane, or tris(8-hydroxy-quinolinol)aluminum, to form a hole injected layer 113A corresponding to a lower layer of a light emitting device 113 is ejected using an ink jet applying apparatus, whereby the electroluminescence material 140A is selectively applied in an area at a predetermined position surrounded by steps 135.

The electroluminescence material 140A is preferably a functional liquid as a precursor in the state dissolved in a solvent.

Then, as shown in FIG. 26(B), the solvent contained in the electroluminescence material 140A is evaporated by heating, light illumination or the like to form the hole injected layer 113A as a solid and thin film on the pixel electrode 111. Preferably, by repeating the steps shown in FIGS. 26(A) and 26(B) plural times as required, the hole injected layer 113A having a sufficient thickness is formed as shown in FIG. 26(C).

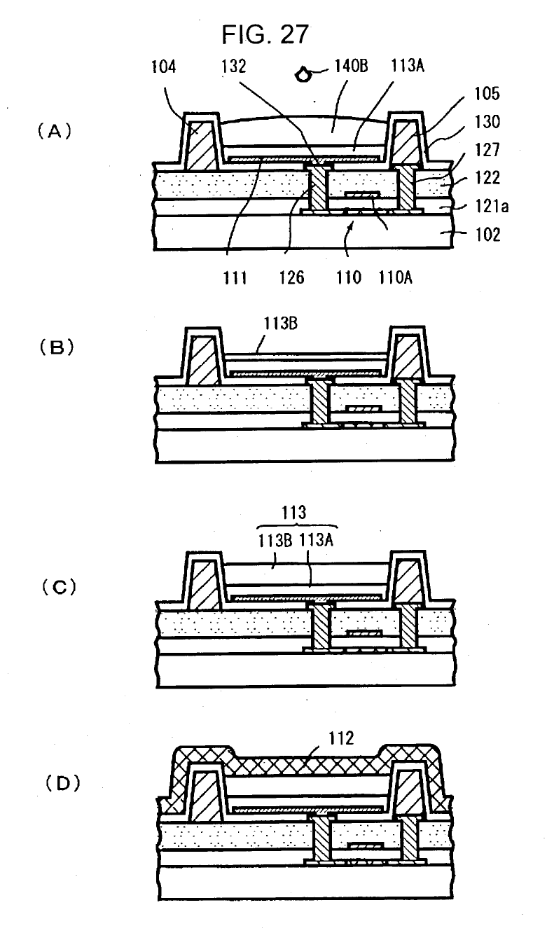

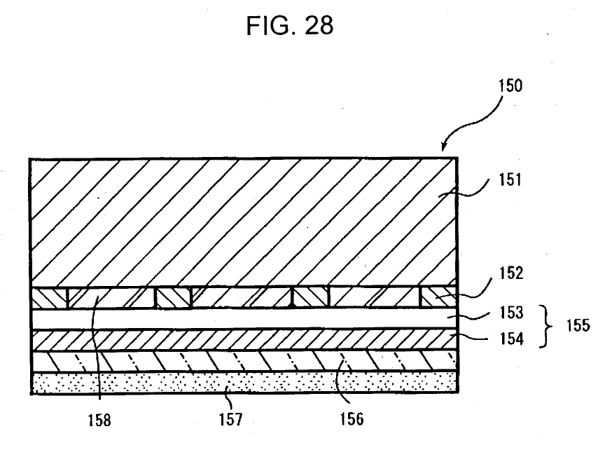

Then, as shown in FIG. 27(A), with the upper surface of the display board 102 being faced upward, an electroluminescence material 140B, e.g., cyanopolyphenylene vinylene, polyphenylene vinylene, or polyalkylphenylene, to form an organic semiconductor film 113B corresponding to an upper layer of the light emitting device 113 is ejected by the ink jet process, whereby the electroluminescence material 140B is selectively applied in the area surrounded by the steps 135.

The electroluminescence material 140B is preferably a functional liquid as an organic fluorescent material in the state dissolved in a solvent.

Then, as shown in FIG. 27(B), the solvent contained in the electroluminescence material 140B is evaporated by heating, light illumination or the like to form the organic semiconductor film 113B as a solid and thin film on the hole injected layer 113A.

Preferably, by repeating the steps shown in FIGS. 27(A) and 27(B) plural times, the organic semiconductor film 113B having a sufficient thickness is formed, as shown in FIG. 27(C), so that the electroluminescence light emitting device 113 is constituted by the hole injected layer 113A and the organic semiconductor film 113B.

(3) Formation of Reflecting Electrode

Finally, in the fifth embodiment, a reflecting electrode (counter electrode) 112 is formed over the display board 102 on the entire surface or in the stripe form, as shown in FIG. 27(D). By thus forming the reflecting electrode, an electroluminescence device 101 having a sandwich structure can be manufactured.

3. Modifications of Electroluminescence Device

As modifications of the electroluminescence device manufacturing apparatus according to the fifth embodiment, the present invention is also preferably applicable to any of a striped display in which three kinds of luminous pixels corresponding to RGB pixels or YMC pixels are formed in a striped pattern, an active matrix display including, as described above, transistors to control, per pixel, a current supplied to the luminous layer by a drive IC, and a passive matrix display.

[Sixth Embodiment]

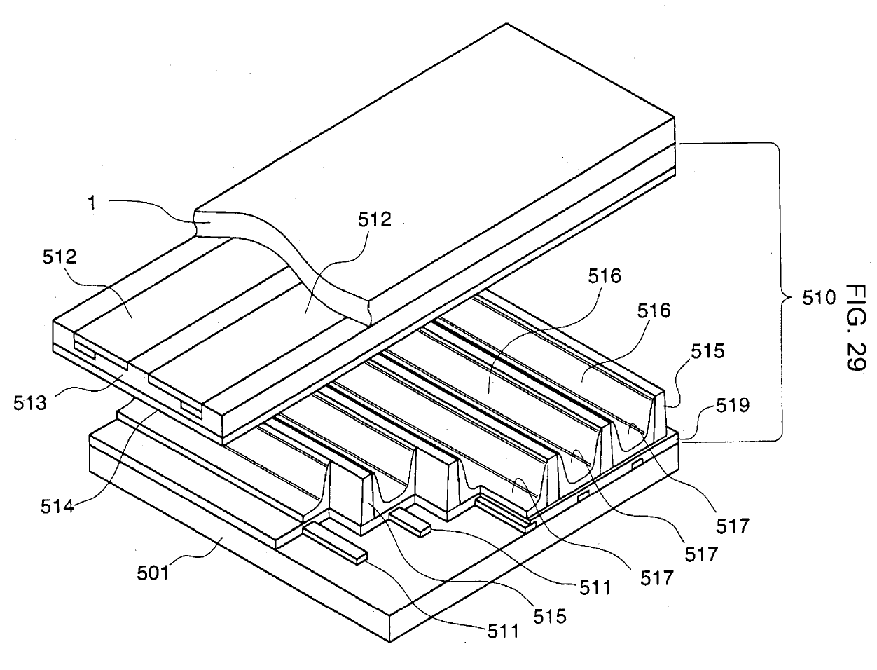

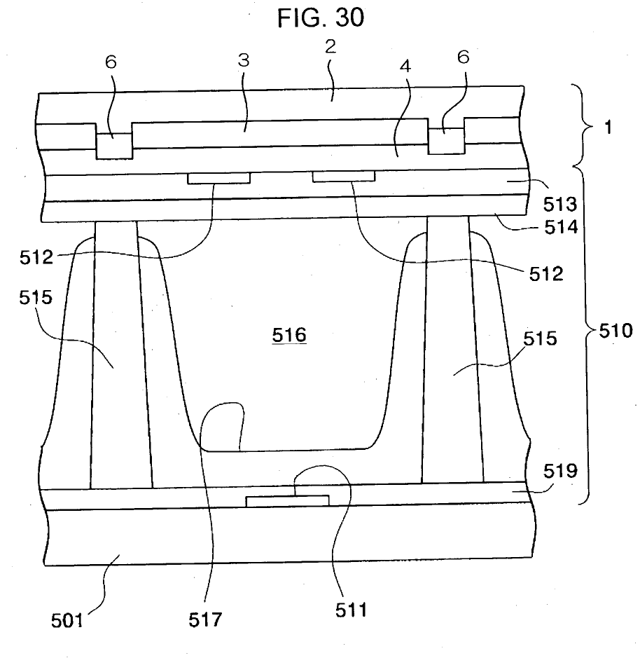

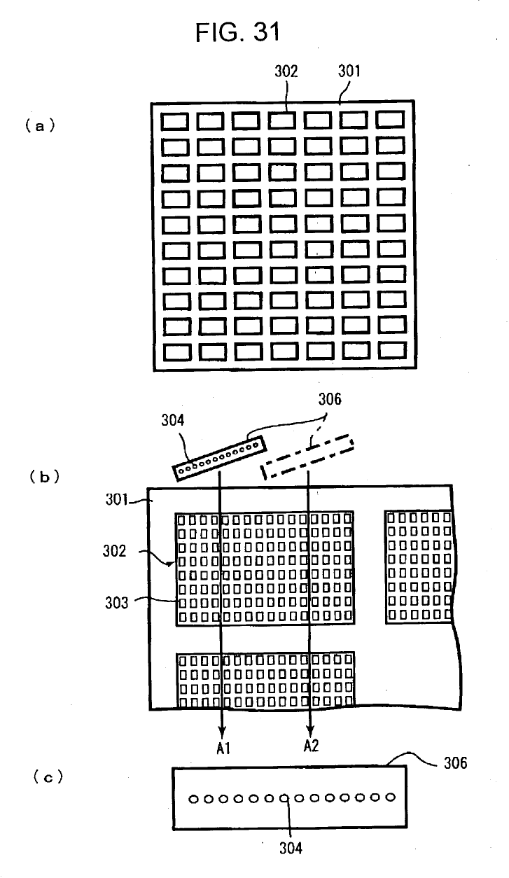

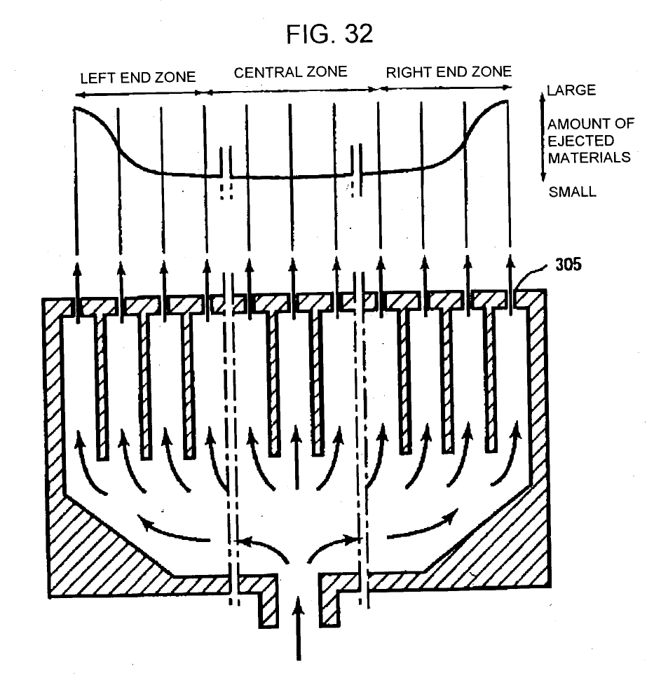

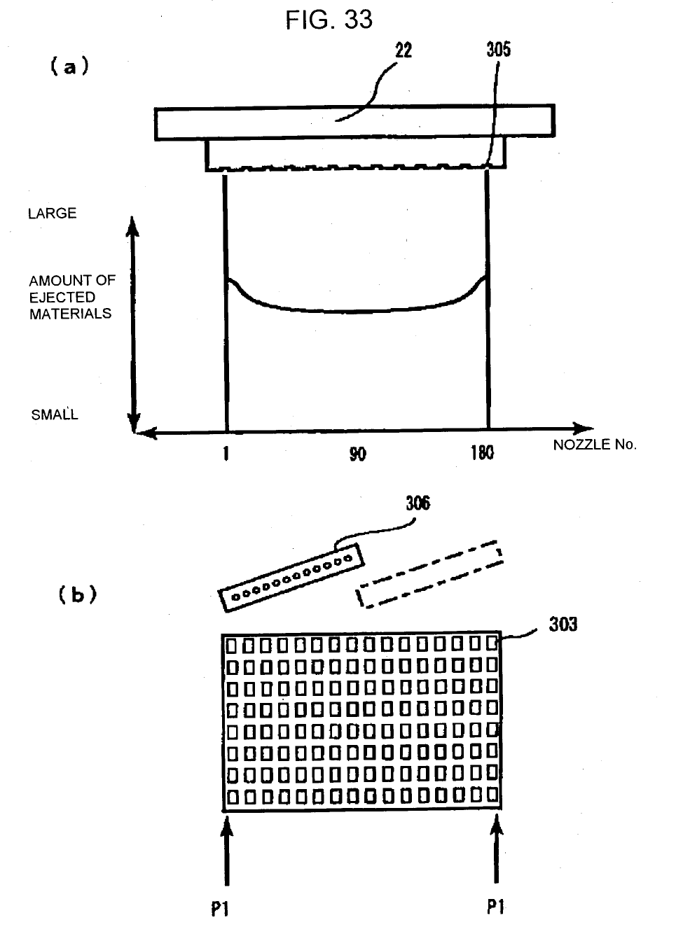

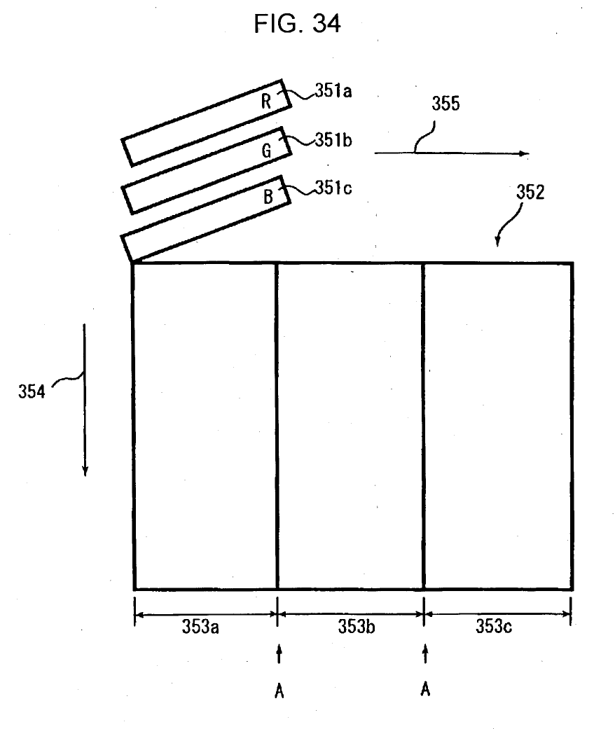

A display device of a sixth embodiment according to the present invention will be described below with reference to the drawings. FIG. 29 is an exploded perspective view of a plasma display panel 500 of this sixth embodiment, and FIG. 30 is a basic conceptual view of the plasma display panel 500. The plasma display panel 500 of this sixth embodiment includes a color filter 1 that is the same as the color filter 1 described above in connection with the fourth embodiment. The plasma display panel 500 is constructed with the color filter 1 disposed on the observing side. The color filter 1 comprises a substrate 2, filter elements (colored layer) 3, a partition wall 6, and a protective layer 4.

The plasma display panel 500 primarily comprises a glass substrate 501 and the color filter 1, which are arranged in a space relation to face each other, and a discharge display section 510 formed between them. The discharge display section 510 comprises an assembly of numerous discharge chambers 516, and among the numerous discharge chambers 516, every three discharge chambers 516 provide one set that constitutes one pixel. Thus, the discharge chambers 516 are provided respectively corresponding to the individual filter elements 3 (3R, 3G, 3B) of the color filter 1 described above.

Address electrodes 511 are formed on the upper surface of the glass substrate 501 in a striped pattern at a predetermined interval, and a dielectric layer 519 is formed so as to cover the upper surfaces of the address electrodes 511 and the substrate 501. Further, partition walls 515 are each formed on the dielectric layer 519 along the address electrodes 511 to position between the adjacent address electrodes 511 and 511. The partition walls 515 are also each divided in the direction perpendicular to the address electrodes 511 (though not shown) at predetermined positions in the longitudinal direction with a predetermined interval. In other words, basically, a rectangular area is defined by two adjacent partition walls located on both sides of the address electrode 511 in the direction of width thereof and by two other adjacent partition walls extending in the direction perpendicular to the address electrode 511. The discharge chambers 516 are each formed corresponding to the rectangular area. Each set of those three rectangular areas constitutes one pixel. Also, a fluorescent substance 517 is disposed in each of the rectangular areas defined by the partition walls 515.

On the color filter 1 side, a plurality of display electrodes 512 are formed to extend in the direction perpendicular to the address electrodes 511 in a striped pattern at a predetermined interval, and a dielectric layer 513 is formed so as to cover the plurality of display electrodes 512. Further, a protective film 514 made of MgO, for example, is formed on the surface of the dielectric layer 513. For the sake of convenience in drawing, in FIG. 30, the direction in which the display electrodes 512 are extended differs from the actual one. The substrate 501 and the substrate 2 of the color filter 1 are bonded to each other such that the address electrodes 511 and the display electrodes 512 are positioned perpendicularly to each other in a facing relation. The discharge chambers 516 are formed by evacuating spaces defined by the substrate 501, the partition walls 515, and the protective film 514 formed on the color filter 1 side, and then enclosing a rare gas in the evacuated spaces. Additionally, the display electrodes 512 are formed on the color filter 1 side such that two display electrodes are arranged for each discharge chamber 516.

The address electrodes 511 and the display electrodes 512 are connected to AC power supplies (not shown), and electric power is selectively supplied to those electrodes so that the fluorescent substances in the discharge display section 510 at required positions are excited to emit white light. Color display can be provided by observing the emitted white light through the color filter 1.

In this sixth embodiment, the fluorescent substances 517 in the discharge chambers 516 may be disposed using the above-described droplet ejecting method and apparatus. Also, while the plasma display panel 500 of this sixth embodiment includes the color filter 1 that is the same as that shown in the fourth embodiment, the fluorescent substances 517 in the discharge chambers 516 may be selected so as to emit colored fluorescent lights of RGB, for example, instead of providing the color filter 1. In such a case, a board for a plasma display can also be formed by ejecting liquid materials to introduce the fluorescent substances in the areas (corresponding to the discharge chambers 516) defined by the partition walls 515 using the above-described droplet ejecting method and apparatus.

[Other Embodiments]

While the present invention has been described above in connection with preferred embodiments, the present invention is not limited to the above-described first to sixth embodiments, but can also be implemented in any other suitable practical structures and shapes, including modifications given below, so long as the object of the present invention can be achieved.

Application fields of the ejecting method, etc. of the present invention are not limited to the color filter and the apparatus for manufacturing the same, the liquid crystal display including the color filter and the apparatus for manufacturing the same, the electroluminescence device and the apparatus for manufacturing the same, as well as the plasma display and the apparatus for manufacturing the same, which have been described above. The present invention is likewise applicable to other various electro-optic devices such as an FED (Field Emission Display), an electrophresis device, and a thin Braun tube, i.e., CRT (Cathode-Ray Tube).

Further, the ejecting method, etc. of the present invention can be employed in steps of manufacturing various boards contained in electro-optic devices.

Examples of applicable manufacturing steps include a step of ejecting a liquid metal, an electrically conductive material, etc. and forming metallic traces to form electrical wiring on a printed circuit board, a step of forming fine micro-lenses, a step of applying, only to required areas, a resist to be coated on a substrate, a step of forming projections, minute white patterns, etc. on a light transmissive substrate, etc. to scatter light, a step of ejecting RNA (ribonucleic acid) to spike spots arrayed in the form of a matrix on a DNA (deoxyribonucleic acid) chip for thereby fabricating a fluorescence label probe, and ejecting a sample, an antibody, DNA (deoxyribonucleic acid), etc. to dot-like positions partitioned on a substrate for thereby forming a bio-chip.

According to the present invention, a plurality of liquid materials are successively ejected from corresponding nozzle rows, and respective positions of ejection start and/or end points for the plurality of liquid materials are set different from each other. It is therefore possible to efficiently provide a color filter having uniform electro-optic characteristics, etc. in the planar direction, a liquid crystal display using the color filter, an electroluminescence device with a fluorescent medium having a uniform thickness, a plasma display panel with a luminous medium having a uniform thickness, and so on.

Accordingly, the liquid crystal display, etc. obtained by the present invention can be preferably employed in various electro-optic devices, such as a personal computer, cellular phone, PHS (Personal Handyphone System), electronic notebook, pager, POS (Point of Sales) terminal, IC card, mini-disk player, liquid crystal projector, engineering work station, word processor, TV set, video cassette recorder of view finder type or monitor direct-viewing type, electronic calculator, car navigation device, touch panel device, clock, and a game machine.

What is claimed is:

1. A liquid material ejecting method using a droplet ejection head, wherein a plurality of liquid materials are successively ejected toward a substrate from corresponding nozzle rows while scanning said droplet ejection head or said substrate, and respective positions of ejection start and/or end points for the liquid materials are set different from each other.

2. A liquid material ejecting method according to claim 1, wherein positions of both or one ends of said nozzle rows are made different from each other in one- or two-dimensional directions, whereby the respective positions of the ejection start and/or end points for the liquid materials are set different from each other.

3. A liquid material ejecting method according to claim 1, wherein ejection widths of the liquid materials are set substantially equal to each other.

4. A liquid material ejecting method according to claim 3, wherein said droplet ejection head is prepared in plural, and widths of said nozzle rows in a direction crossing a scan direction of said droplet ejection head are set substantially equal to each other, whereby the ejection widths of the liquid materials are set substantially equal to each other.

5. A liquid material ejecting method according to claim 1, wherein ejection widths of the liquid materials are set different from each other, and the positions of the ejection start points or the positions of the ejection end points for the liquid materials are set substantially coincident with each other.

6. A liquid material ejecting method according to claim 5, wherein said droplet ejection head is prepared in plural, and widths of said nozzle rows in a direction crossing a scan direction of said droplet ejection head are set different from each other, whereby the ejection widths of the liquid materials are set different from each other.

7. A liquid material ejecting method according to claim 1, wherein in applying the liquid materials to end portions of said substrate using the nozzle rows, one ore more nozzle rows located outside an area of said substrate are not used, and one ore more nozzle rows located inside the area of said substrate are used.

8. A liquid material ejecting apparatus using a droplet ejection head, comprising nozzle rows provided on said droplet ejection head corresponding to a plurality of liquid materials, and a control unit for successively ejecting the plurality of liquid materials from the corresponding nozzle rows while scanning said droplet ejection head or a substrate, such that respective positions of ejection start and/or end points for the liquid materials are different from each other.

9. A liquid material ejecting apparatus according to claim 8, wherein said droplet ejection head is arranged obliquely with respect to a scan direction of said droplet ejection head.

10. A liquid material ejecting apparatus according to claim 8, wherein said nozzle rows corresponding to the plurality of liquid materials are arranged on one droplet ejection head.

11. A liquid material ejecting apparatus according to claim 8, wherein said nozzle rows corresponding to the plurality of liquid materials are disposed respectively on a plurality of droplet ejection heads.

12. A color filter manufacturing method using a droplet ejection head, wherein a plurality of color filter materials are successively ejected from corresponding nozzle rows while relatively scanning said droplet ejection head or a substrate, and respective positions of ejection start and/or end points for the color filter materials are set different from each other.

13. A color filter obtained by a color filter manufacturing method according to claim 12.

14. A liquid crystal display including a color filter according to claim 13.

15. An electroluminescence device manufacturing method using a droplet ejection head, wherein a plurality of electroluminescence materials are successively ejected from corresponding nozzle rows while scanning said droplet ejection head or a substrate, and respective positions of ejection start and/or end points for the electroluminescence materials are set different from each other.

16. An electroluminescence device obtained by an electroluminescence device manufacturing method according to claim 15.

17. A plasma display panel manufacturing method using a droplet ejection head, wherein a plurality of plasma luminous materials are successively ejected from corresponding nozzle rows while scanning said droplet ejection head or a substrate, and respective positions of ejection start and/or end points for the plasma luminous materials are set different from each other.

18. A plasma display panel obtained by a plasma display panel manufacturing method according to claim 17.

19. A liquid material ejecting method comprising:
a scanning step of successively ejecting, from a plurality of nozzle rows, corresponding different liquid materials toward a substrate while scanning said plurality of nozzle rows or said substrate in a predetermined direction,
wherein, in said scanning step,
an area of said substrate, over which one of said plurality of nozzle rows passes, is partly overlapped with an area of said substrate, over which another nozzle row passes, and
both end positions of one of said plurality of nozzle rows are different from both end positions of another nozzle row in a direction perpendicular to the predetermined direction.

20. A liquid material ejecting method comprising:
a scanning step of successively ejecting, from a plurality of nozzle rows, corresponding different liquid materials toward a substrate while scanning said plurality of nozzle rows or said substrate in a predetermined direction,
wherein, in said scanning step,
an area of said substrate, over which one of said plurality of nozzle rows passes, is partly overlapped with an area of said substrate, over which another nozzle row passes,
a first end position of one of said plurality of nozzle rows is substantially the same as a first end position of another nozzle row in a direction perpendicular to the predetermined direction, and
a second end position of one of said plurality of nozzle rows is different from a second end position of another nozzle row in the direction perpendicular to the predetermined direction.

21. A liquid material ejecting method comprising:
a scanning step of successively ejecting, from first, second and third nozzle rows, corresponding first, second and third liquid materials toward a substrate while scanning said first, second and third nozzle rows or said substrate in a predetermined direction,
wherein, in said scanning step,
areas of said substrate, over which said first, second and third nozzle rows pass, are partly overlapped with each other, and
both end positions of said first, second and third nozzle rows are different from each other in a direction perpendicular to the predetermined direction.

22. A liquid material ejecting method comprising:
a scanning step of successively ejecting, from first, second and third nozzle rows, corresponding first, second and third liquid materials toward a substrate while scanning said first, second and third nozzle rows or said substrate in a predetermined direction,
wherein, in said scanning step,
areas of said substrate, over which said first, second and third nozzle rows pass, are partly overlapped with each other,
first end positions of said first, second and third nozzle rows are substantially the same in a direction perpendicular to the predetermined direction, and
second end positions of said first, second and third nozzle rows are different from each other in the direction perpendicular to the predetermined direction.
